(19) United States
(12) Patent Application Publication
(10) Pub. No.: US 2026/0101449 A1
(43) Pub. Date: Apr. 9, 2026

(54) CONTROL DEVICE HAVING BUTTONS FOR CONTROLLING ONE OR MORE ELECTRICAL LOADS

(71) Applicant: Lutron Technology Company LLC, Coopersburg, PA (US)

(72) Inventors: Nikhil V. Bhate, East Norriton, PA (US); Joseph M. Nichols, Boyertown, PA (US)

(73) Assignee: Lutron Technology Company LLC, Coopersburg, PA (US)

(21) Appl. No.: 19/349,530

(22) Filed: Oct. 3, 2025

Related U.S. Application Data
(60) Provisional application No. 63/702,949, filed on Oct. 3, 2024.
(60) Provisional application No. 63/707,553, filed on Oct. 15, 2024.

(51) Int. Cl. H05K 5/00; H01H 13/14; H05K 5/03

(52) U.S. Cl. CPC H05K 5/0017; H01H 13/14; H05K 5/03

(57) ABSTRACT

A control device for controlling an amount of power delivered to one or more electrical loads may include a cover plate assembly, a button assembly, and a control module. The button assembly may include a button frame and a plurality of buttons supported by the button frame. Each of the plurality of buttons may define a rear surface and a post extending from the rear surface. The control module may include a printed circuit board and a plurality of switches configured to be actuated by the posts when the respective button is pressed. An adapter of the cover plate assembly may define a plurality of spring arms that abut the button frame of the button assembly to push the button frame against the control module and deflect independently in a transverse direction to align the posts of the plurality of buttons with the plurality of switches.

### CROSS-REFERENCE TO RELATED APPLICATIONS

This application claims the benefit of U.S. Provisional Patent Application No. 63/702,949 , filed Oct. 3, 2024 and U.S. Provisional Patent Application No. 63/707,553 , filed Oct. 15, 2024, the entire disclosures of which are hereby incorporated by reference herein in their respective entireties.

### BACKGROUND

Load control devices may be used to control the amount of power delivered from a power source, such as an alternating-current (AC) power source, to one or more electrical loads. An example of such a load control device is a wall-mounted dimmer switch. Load control devices may be integrated into home automation systems

Home automation systems, which have become increasingly popular, may be used by homeowners to integrate and/or control multiple electrical and/or electronic devices in their homes. For example, a homeowner may connect devices such as appliances, lights, blinds, thermostats, cable or satellite boxes, security systems, telecommunication systems, and the like to each other via a wireless network.

The homeowner may control such devices using a central (e.g., automated) controller, a dedicated remote control device (e.g., a wall-mounted keypad), a user interface provided via a phone, tablet, computer, or other device that is directly connected to a home network or remotely connected via the Internet, and so on. These devices may communicate with each other and/or with a control device, for example to improve efficiency, convenience, and/or usability of the devices.

Dedicated remote control devices, such as wall-mounted keypads, may be manufactured to be aesthetically pleasing. For example, wall-mounted keypads may include cover plates (e.g., faceplates) and/or buttons made of metal, glass, or other materials to lend the keypads a luxury aesthetic when compared to traditional plastic keypads.

The buttons and/or cover plates of such keypads may be marked with indicia. The indicia may be representative of functions that the keypad is configured to execute or that the keypad is configured to cause to be executed. Such indicia are typically marked on outer surfaces of the keypad. For example, indicia may be painted onto the outer surfaces of buttons of the keypad. However, keypads having such indicia may exhibit limitations. For instance, indicia that is painted onto the outer surface of a button may not be visible to a user in low light. Moreover such indicia may at least partially wear off over time as the keypad is operated, thereby diminishing the aesthetic of the keypad.

### SUMMARY

A control device may be configured for use in a load control system for controlling an amount of power delivered to one or more electrical loads. The control device may include a cover plate assembly, a button assembly, and a control module. The cover plate assembly may include a cover plate and an adapter attached to a rear surface of the cover plate. The cover plate may define an opening. The button assembly may include a button frame and a plurality of buttons supported by the button frame. The plurality of buttons may be configured to be received within the opening of the cover plate of the cover plate assembly. Each of the plurality of buttons may define a rear surface and a post extending from the rear surface. The control module may include a printed circuit board and a plurality of switches mounted to the printed circuit board. Each of the plurality of switches may be configured to be actuated by one of the posts of the plurality of buttons when the respective button is pressed. The button assembly may be configured to be releasably secured to the control module. The adapter may define a plurality of spring arms that abut the button frame of the button assembly to push the button frame against the control module. Each of the plurality of spring arms may be configured to deflect independently in a transverse direction to align the posts of the plurality of buttons with the plurality of switches.

The adapter may include a frame that defines an adapter opening through which the plurality of buttons extend. The adapter may define a plurality of first tabs that extend from the frame proximate to the opening. The plurality of first tabs may be configured to secure the cover plate assembly and the button assembly to the control module. The control module may include a plurality of clips that are configured to engage the plurality of first tabs. The adapter may define a plurality of second tabs that extend from the frame proximate to the opening. Each of the plurality of second tabs may define an aperture. The button frame may include a plurality of projections on a top side and a bottom side of the button frame. Each of the plurality of projections may be configured to be received by a respective one of the plurality of second tabs to hold the button assembly against the cover plate assembly. The cover plate may include one or more posts that extend rearward from the rear surface of the cover plate. The one or more posts may be configured to align the adapter with the cover plate.

The button frame may define a plate portion that surrounds a button frame opening that is configured to receive the plurality of buttons. The plurality of spring arms may be configured to abut the plate portion of the button frame as the cover plate assembly is pressed into engagement with the control module. Each of the plurality of spring arms may be configured to deflect independently based on alignment of the control module with the structure. Each of the plurality of spring arms may deflect to enable proper alignment of the plurality of buttons with the plurality of switches such that a rear surface of each of the posts is substantially parallel to a respective one of the switches. The adapter may include one or more posts extending from a rear surface of the adapter. The one or more posts extending from the rear surface of the adapter may be configured to be received by respective openings on the button frame to align the button assembly with the cover plate assembly.

The button assembly may include a button carrier that is configured to align respective outer surfaces of the plurality of buttons relative to one another. The button assembly may include a single column of buttons. The button assembly may include two columns of buttons with a separating portion located between the two columns of buttons. The control device may include a plurality of light sources mounted to the printed circuit board of the control module. Each of the plurality of buttons may be backlit by a respective one of the plurality of light sources. Each of the plurality of buttons may include an opaque portion and a visible indicator configured to be illuminated by the respective one of the plurality of light sources. The control device may include a plurality of light pipe assemblies configured to direct the light from the plurality of light sources to the visible indicators on the plurality of buttons. Each of the plurality of light pipe assemblies may include a first portion that defines an angled upper surface that is located within a cavity defined by the respective button to direct the light of a corresponding one of the light sources toward the visible indicator.

An assembly that is configured for use in a load control system for controlling an amount of power delivered to one or more electrical loads may include a cover plate and a button assembly. The cover plate may define a front surface, a rear surface, and an opening extending from the front surface to the rear surface. The cover plate may include a plurality of first tabs that extend rearward from the cover plate. Each of the plurality of first tabs may define an aperture. The button assembly may include a button frame and a plurality of buttons supported by the button frame. The plurality of buttons may be configured to be received within the opening of the cover plate. Each of the plurality of buttons may define a rear surface and a post extending from the rear surface of the respective button. The button frame may include a plurality of projections. Each of the plurality of projections may be configured to be received by the aperture of a respective one of the plurality of first tabs for releasably securing to the button assembly to cover plate.

The assembly may further include a shell comprising a flexible sheet and walls that extend from the flexible sheet and define a recess. The shell may be received in the opening of the cover plate. The plurality of buttons of the button assembly may be configured to be received in the recess of the shell. The shell may include flanges configured to abut the rear surface of the cover plate, for example, to retain the shell in the opening of the cover plate. The cover plate may include two interior walls on opposed sides of the opening of the cover plate. Each of the interior walls may define a slot therethrough. The shell may include wings extending from the flanges. The wings may be configured to extend through the slots in the interior walls of the cover plate to attach the shell to the cover plate. When the flexible sheet is actuated by a user, the flexible sheet may be configured to flex, for example, to allow for actuation of the buttons received in the recess of the shell. The shell may be made from a transparent or translucent material, for example, such that the buttons of the button assembly are visible through the shell.

The cover plate and the button assembly may be configured to be attached to a control module installed in an electrical wallbox. The post of each of the buttons may be configured to actuate a respective one of a plurality of switches on the control module. The cover plate may define a plurality of second tabs that extend rearward from the cover plate. The plurality of second tabs may be configured to secure the cover plate and the button assembly to the control module. The plurality of second tabs may be configured to engage a plurality of clips defined by the control module. Each of the plurality of buttons may be backlit by a respective one of a plurality of light sources mounted to the control module. Each of the plurality of buttons may include an opaque portion and a visible indicator configured to be illuminated by the respective one of the plurality of light sources. The cover plate may include walls extending rearward from the cover plate. The plurality of first tabs may extend rearward from two or more of the walls. The plurality of first tabs may extend rearward from the rear surface of the cover plate. The plurality of projections of the button frame may be located on a top side and a bottom side of the button frame. The cover plate may be a decorative cover plate.

### BRIEF DESCRIPTION OF THE DRAWINGS

FIG. 1 is a block diagram of an example load control system.

FIG. 2 is a front perspective view of an example control device for use in a load control system for controlling the amount of power delivered to one or more electrical loads.

FIG. 3 is a front view of the control device of FIG. 2.

FIG. 4 is a front exploded view of the control device of FIG. 2.

FIG. 5 is a rear perspective view of a cover plate assembly and a button assembly of the example control device of FIG. 2.

FIG. 6 is a front exploded view of the cover plate assembly and the button assembly of FIG. 5.

FIG. 7 is a rear exploded view of the cover plate assembly and the button assembly of FIG. 5.

FIG. 8 is a front exploded view of a control module of the example control device of FIG. 2.

FIG. 9 is a rear exploded perspective view of the control module of FIG. 8.

FIG. 10 is a side cross-section view of the control device of FIG. 2.

FIG. 11 is a perspective view of the control device of FIG. 2 with an example temporary cover plate assembly mounted on the control module of the control device.

FIG. 12 is a front view of the control device of FIG. 2 with the temporary cover plate assembly of FIG. 11.

FIG. 13 is a front exploded view of the control device of FIG. 2 with the temporary cover plate assembly and the button assembly detached from the control module.

FIG. 14 is a rear exploded view of the control device of FIG. 2 with the temporary cover plate assembly and the button assembly detached from the control module.

FIG. 15 is a rear perspective view of the temporary cover plate assembly of FIG. 11 attached to the button assembly.

FIG. 16 is a perspective view of the control device of FIG. 2 with an example temporary cover plate mounted on the control module of the control device.

FIG. 17 is a front view of the control device of FIG. 2 with the temporary cover plate of FIG. 16.

FIG. 18 is a front exploded view of the control device of FIG. 2 with the temporary cover plate and the button assembly detached from the control module.

FIG. 19 is a rear exploded view of the control device of FIG. 2 with the temporary cover plate and the button assembly detached from the control module.

FIG. 20 is a rear perspective view of the temporary cover plate of FIG. 16 attached to the button assembly.

FIG. 21 is a front perspective view of another example control device for use in a load control system for controlling the amount of power delivered to one or more electrical loads.

FIG. 22 is a front view of the example control device of FIG. 21.

FIG. 23 is a rear perspective view of a cover plate assembly and a button assembly of the example control device of FIG. 21.

FIG. 24 is a front exploded view of the cover plate assembly and the button assembly of FIG. 23.

FIG. 25 is a rear exploded view of the cover plate assembly and the button assembly of FIG. 23.

FIG. 26 is a front exploded view of a control module of the example control device of FIG. 21.

FIG. 27 is a rear exploded perspective view of the control device module of FIG. 26.

FIG. 28 is a block diagram of an example control device.

### DETAILED DESCRIPTION

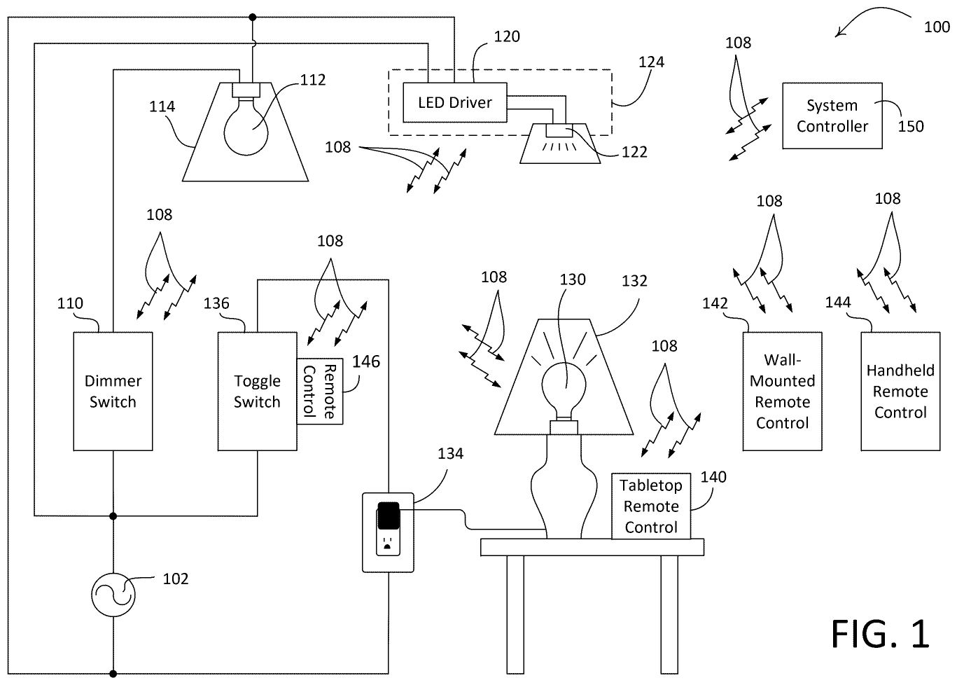

FIG. 1 is a simplified block diagram of an example load control system 100 (e.g., a lighting control system). The load control system 100 may comprise one or more load control devices (e.g., such as lighting control devices) for controlling one or more electrical loads (e.g., such as lighting loads). For example, the load control devices of the load control system 100 may comprise a wall-mounted load control device, such as a dimmer switch 110, which may be electrically coupled between a power source 102 and a light source, such a lighting load 112 (e.g., an external lighting load). The power source 102 may comprise, for example, an alternating-current (AC) power source (e.g., as shown in FIG. 1) and/or a direct-current (DC) power source. The lighting load 112 may comprise a dimmable light source (e.g., such as an incandescent lamp, a halogen lamp, and/or a dimmable light-emitting diode (LED) light source) installed in a lighting fixture 114, such as a ceiling-mounted downlight fixture. The dimmer switch 110 may be configured to control the lighting load 112 using a phase-control dimming technique (e.g., the lighting load 112 may be responsive to a phase-control signal generated by the dimmer switch 110). For example, the dimmer switch 110 may be configured to adjust an intensity level (e.g., a brightness) of the lighting load 112 using the phase-control dimming technique. The dimmer switch 110 may be configured to adjust the intensity level of the lighting load 112 between a low-end intensity level (e.g., a minimum intensity level) and a high-end intensity level (e.g., a maximum intensity level).

The lighting load 112 may be configured to adjust the intensity level of light emitted by the lighting load 112 in response to a firing angle of the phase-control signal received from the dimmer switch 110. In some examples, the lighting load 112 may be configured to also adjust a color (e.g., color temperature and/or full color) of the light emitted by the lighting load 112 in response to the phase-control signal according to a relationship between the color temperature and the intensity level set by the phase-control signal (e.g., according to a warm-dim curve). The dimmer switch 110 may comprise a user interface, including one or more buttons configured to be actuated by a user for controlling the lighting load 112. In addition, the dimmer switch 110 may be configured to receive messages (e.g., digital messages) via communication signals, such as wireless signals, e.g., radio-frequency (RF) signals 108. For example, the message may include commands for causing the dimmer switch 110 to control the lighting load 112. In some examples, in addition to generating the phase-control signal, the dimmer switch 110 may be configured to transmit messages including commands for controlling the lighting load 112 (e.g., and/or other lighting loads in the load control system 100). For example, the lighting load 112 may be configured to adjust the intensity level and/or the color (e.g., color temperature and/or full color) of the light emitted by the lighting load 112 in response to the commands received in the messages (e.g., from the dimmer switch 110) via the RF signals 108.

The load control devices of the load control system 100 may also comprise a remote load control device, such as an LED driver 120, for controlling a lighting load, such as LED light source 122 (e.g., an external lighting load). The LED driver 120 may be electrically coupled to the power source 102 for receiving power and may be configured to control the amount of power delivered to the LED light source 122 for controlling an intensity level and/or color (e.g., full color and/or color temperature) of the LED light source 122. For example, the integral LED light source may comprise one more LED circuits of different colors that may be mixed together to control a cumulative light emitted by the integral LED light source. The LED light source 122 may comprise, for example, an LED light engine that is external to a housing of the LED driver 120 and installed with the LED driver 120 in a lighting fixture 124, such as a ceiling-mounted downlight fixture. For example, the LED driver 120 may be a multi-channel LED driver having multiple channels (e.g., outputs) for controlling the differently-colored LED circuits of the LED light source 122. The LED driver 120 may be configured to control the magnitude of drive currents conducted through each of the LED circuits of the LED light source 122 to control the intensity level and/or color of the light emitted by the LED light source 122. The LED driver 120 may be configured to adjust the intensity level of the LED light source 122 between a low-end intensity level (e.g., a minimum intensity level) and a high-end intensity level (e.g., a maximum intensity level). The LED driver 120 may be configured to receive messages (e.g., digital messages) via the RF signals 108. For example, the message may include commands for causing the LED driver 120 to control the LED light source 122. The LED driver 120 may be configured to adjust the intensity level and/or the color (e.g., color temperature and/or full color) of the light emitted by the LED light source 122 in response to the commands received in the messages via the RF signals 108. In some examples, the LED driver 120 may be integrated into the LED light source 122, and the LED light source 122 may be responsive to the command received in the messages via the RF signals 108.

In addition, the load control devices of the load control system 100 may comprise a controllable light source 130 (e.g., such as a smart lamp or smart bulb). The controllable light source 130 may comprise an integral lighting load (e.g., an integral LED light source) included in the same housing as a load control circuit (e.g., an LED driver circuit) for controlling the integral LED light source. For example, the integral LED light source may comprise one more LED circuits of different colors that may be mixed together to control a cumulative light emitted by the integral LED light source. The controllable light source 130 may be installed into, for example, a table lamp 132 that may be plugged into an electrical outlet 134 (e.g., an electrical receptacle), which may receive power from the power source 102 for powering the controllable light source 130. For example, the electrical outlet 134 may be electrically coupled to the power source 102 via a toggle switch 136 (e.g., a mechanical switch). When the toggle switch 136 is on (e.g., is in a conductive state), the controllable light source 130 may receive power from the power source 102 (e.g., be powered). When the toggle switch 136 is off (e.g., is in a non-conductive state), the controllable light source 130 may be disconnected from the power source 102 (e.g., be unpowered). The load control circuit of the controllable light source 130 may be configured to control an intensity level (e.g., a brightness) and/or a color (e.g., color temperature and/or full color) of the cumulative light emitted by the integral lighting load. The controllable light source 130 may be configured to receive messages (e.g., digital messages) via the wireless signals, e.g., the RF signals 108. For example, the message may include commands for causing the controllable light source 130 to control the integral lighting load. The controllable light source 130 may be configured to adjust the intensity level and/or the color (e.g., color temperature and/or full color) of the light emitted by the integral LED light source in response to the commands received in the messages via the RF signals 108.

The lighting loads of the load control system 100 (e.g., the lighting load 112 controlled by the dimmer switch 110, the LED light source 122 controlled by the LED driver 120, and/or the LED light source of the controllable light source 130) may be capable of multiple means of control. For example, one or more of the lighting loads may be intensity-control capable when the lighting loads are capable of being controlled in response to intensity-adjustment commands. In addition, one or more of the lighting loads may be color-temperature-control capable when the lighting loads are capable of being controlled in response to color-temperature-adjustment commands. Further, one or more of the lighting loads may be full-color-control capable when the lighting loads are capable of being controlled in response to full-color-adjustment commands. For example, the lighting load 112 controlled by the dimmer switch 110 may be intensity-control capable (e.g., only intensity-control capable) when the lighting load 112 may be controlled via a phase-control signal (e.g., only via a phase-control signal). In addition, the LED light source 122 controlled by the LED driver 120 and the LED light source of the controllable light source 130 may be intensity-control capable as well as color-temperature-control capable and/or full-color-control capable. For example, some lighting loads may be color-temperature-control capable (e.g., only color-temperature-control capable) when the color of the light emitted by the lighting load may be controlled (e.g., only be controlled) to colors (e.g., white colors) along the black body curve. In addition, some lighting loads may be color-control capable when color of the light emitter by the lighting load may be controlled to multiple colors (e.g., as determined by an x-chromaticity coordinate and a y-chromaticity coordinate) within a gamut in the color space (e.g., not limited to white colors on the black body curve). Typically, those lighting loads that are full-color-control capable are also color-temperature-control capable. A load control device that is controlling a lighting load that is both color-temperature-control capable and full-color-control capable may operate (e.g., only operate) in one or the other of the color-temperature-control mode or the full-color-control mode at a time.

The load control system 100 may include one or more input control devices for controlling the load control devices (e.g., controlling the intensity levels of the lighting load 112 controlled by the dimmer switch 110, the LED light source 122 controlled by the LED driver 120, and/or the LED light source of the controllable light source 130). For example, the input control devices of the load control system 100 may comprise, a tabletop remote control device 140, a wall-mounted remote control device 142, a handheld remote control device 144, and/or a retrofit remote control device 146 as shown in FIG. 1. The load control devices (e.g., the dimmer switch 110, the LED driver 120, and/or the controllable light source 130) may be controlled substantially in unison, or be controlled individually. The input control devices may be configured to control the load control devices to turn on and off the lighting load 112 controlled by the dimmer switch 110, the LED light source 122 controlled by the LED driver 120, and/or the controllable light source 130. The input control devices may be configured to control the intensity levels of the lighting load 112 controlled by the dimmer switch 110, the LED light source 122 controlled by the LED driver 120, and/or the controllable light source 130. The input control devices may be configured to control the color of light emitted by the lighting load 112 and/or the controllable light source 130 (e.g., by controlling a color temperature of the lighting loads or by applying full color control to the lighting loads). The input control devices may be configured to control the intensity level and/or the color temperature of each of the lighting load 112, the LED light source 122, and the controllable light source 130 to an absolute level (e.g., to a particular intensity level, such as to 50%), and/or by a relative amount (e.g., by a particular amount, such as by 10%). The input control devices may be configured to use full color control to control color of each of the lighting load 112, the LED light source 122, and the controllable light source 130 to an absolute level (e.g., to a particular full color).

The input control device may be configured to be responsive to an input and transmit control data in one or more messages via the RF signals 108 for controlling the lighting load 112, the LED light source 122, and/or the controllable light source 130 based on the input. For example, the input may comprise a detection of an actuation of a button of the input control device by a user. The control data may include commands and/or other information (e.g., such as identification information) for controlling the lighting load 112, the LED light source 122, and/or the controllable light source 130. In some examples, the dimmer switch 110 may be configured to transmit messages via the RF signals 108 for controlling other lighting loads, such as the LED light source 122 and/or the integral LED light source of the controllable light source 130.

The input control devices (e.g., the tabletop remote control device 140, the wall-mounted remote control device 142, the handheld remote control device 144, and/or the retrofit remote control device 146) may be configured to receive an input and may generate and transmit a message (e.g., including control data, such as commands) for controlling the lighting load 112, the LED light source 122, and/or the controllable light source 130 in response to the input. The tabletop remote control device 140 may be configured to be placed on a surface (e.g., a table). The wall-mounted remote control device 142 may be configured to be mounted to a wall (e.g., directly to a wall) and/or to an electrical wallbox. The handheld remote control device 144 may be sized to fit into a user's hand. The tabletop remote control device 140, the wall-mounted remote control device 142, the handheld remote control device 144, and/or the retrofit remote control device 146 may be powered by a direct-current (DC) power source (e.g., a battery or an external DC power supply plugged into an electrical outlet). In some examples, the wall-mounted remote control device 142 may be configured to be electrically connected to the power source 102 for receiving power (e.g., when the wall-mounted remote control device 142 is mounted to the electrical wallbox).

The retrofit remote control device 146 may be configured to be mounted to a light switch, such as the toggle switch 136 (e.g., which may be pre-existing in the lighting control system 100). As an example, a consumer may replace an existing lamp with the controllable light source 130, adjust the toggle switch 136 that is coupled to the controllable light source 130 to the on position, install (e.g., mount) the retrofit remote control device 146 onto the toggle switch 136, and associate the retrofit remote control device 146 with the controllable light source 130. As shown, the toggle switch 136 is coupled (e.g., via a series electrical connection) between the power source 102 and the electrical outlet 134 into which the table lamp 132 in which the controllable light source 130 is installed may be plugged (e.g., as shown in FIG. 1). Alternatively, the toggle switch 136 may be coupled between the power source 102 and one or more lighting loads without the electrical outlet 134.

The load control system 100 may comprise a system controller 150. For example, the system controller 150 may operate as an intermediary device and/or a central processing device for one or more other devices in the load control system 100. The system controller 150 may be configured to communicate messages (e.g., digital messages) to and from the control devices (e.g., the input control devices and the load control devices of the lighting control system 100). The system controller 150 may be configured to receive messages from the input control devices (e.g., the tabletop remote control device 140, the wall-mounted remote control device 142, the handheld remote control device 144, and/or the retrofit remote control device 146) and transmit messages to the load control devices (e.g., the dimmer switch 110, the LED driver 120, and/or the controllable light source 130) in response to the messages received from the input control devices. The system controller 150 may route the messages based on the association information stored thereon. The messages from the input control devices and/or to the load control devices may be communicated via the RF signals 108.

The system controller 150 may be configured to transmit messages to the load control devices for controlling the lighting loads (e.g., the lighting load 112, the LED light source 122, and/or the LED light source of the controllable light source 130) in response to the messages received from the input control devices (e.g., via the RF signals 108). For example, the system controller 150 may receive a message indicating an actuation of a button from an input control device (e.g., such as the tabletop remote control device 140, the wall-mounted remote control device 142, the handheld remote control device 144, and/or the retrofit remote control device 146), and transmit a message to one or more of the load control devices for controlling the lighting loads. For example, the input control devices may be configured to control (e.g., indirectly control) the lighting loads (e.g., the lighting load 112, the LED light source 122, and/or the LED light source of the controllable light source 130) by transmitting messages to the system controller 150 that cause the system controller 150 to transmit messages including commands for controlling the lighting loads to the load control devices. Though the system controller 150 is described as communicating messages between devices in the load control system 100, messages may be communicated directly between devices (e.g., between the input control devices and/or the load control devices). The messages may include configuration data for configuring the input control devices and/or the load control devices, and/or the messages may include control data (e.g., one or more commands) for controlling the lighting loads. The system controller 150 may be coupled to a network, such as a wireless or wired local area network (LAN), e.g., for access to the Internet. The system controller 150 may be wirelessly connected to the network, e.g., using WI-FI technology. The system controller 150 may be coupled to the network via a network communication bus (e.g., an Ethernet communication link).

The load control devices (e.g., the dimmer switch 110, the LED driver 120, and/or the controllable light source 130) may be configured to be controlled by one or more of the input control devices (e.g., the tabletop remote control device 140, the wall-mounted remote control device 142, the handheld remote control device 144, and/or the retrofit remote control device 146) and/or the system controller 150. For example, one or more of the load control devices may be associated with one of the input control devices during a configuration procedure of the load control system 100. During normal operation of the load control system 100, the load control devices may be responsive to messages received from the input control devices to which the respective load control devices are associated.

The input control devices and/or the system controller 150 may be configured to activate a scene (e.g., a preset) associated with the lighting loads (e.g., the lighting load 112, the LED light source 122, and/or the LED light source of the controllable light source 130). A scene may be associated with one or more predetermined settings of the lighting loads, such as an intensity level and/or a color (e.g., a color temperature and/or a full color) of the lighting loads. The scenes may be configured via the input control devices and/or the system controller 150. The input control devices may be configured to switch between different operational modes. An operational mode may be associated with controlling different types of electrical loads or different operational aspects of one or more electrical loads of the load control system 100 (e.g., electrical loads including and/or other than the lighting loads shown in FIG. 1). Examples of operational modes may include a lighting control mode for controlling one or more lighting loads (e.g., which in turn may include an intensity-adjustment mode, a color-temperature-adjustment mode, and/or a full-color-adjustment mode), an entertainment system control mode (e.g., for controlling music selection and/or the volume of an audio system), an heating, ventilation, and air-conditioning (HVAC) system control mode, a winter treatment device control mode (e.g., for controlling one or more shades), and/or the like.

The load control devices (e.g., the dimmer switch 110, the LED driver 120, and/or the controllable light source 130) may be configured to control the respective lighting loads (e.g., the lighting load 112, the LED light source 122, and/or the LED light source of the controllable light source 130) in response to scenes selected by the input control devices and/or the system controller 150 For example, the messages transmitted by the input control devices in response to a scene being selected may include an indication of the selected scene. The load control devices may have stored in memory thereon the particular intensity levels, colors (e.g., full colors), and/or color temperatures to which to control the respective lighting loads in response to the selected scenes. For example, the load control devices may be configured to provide absolute control of the intensity level, color (e.g., full color), and/or color temperature (e.g., to control the intensity level, color, and/or color temperature to absolute levels) in response to the selection of scenes. In response to the selection of a particular scene, the load control devices may be configured to control either color (e.g., full color) and/or the color temperature of a particular lighting load that is a part of the scene. For example, the LED driver 120 and/or the controllable light source 130 may be configured to operate in a color-temperature-control mode to control the color temperature of the integral lighting load, or may operate in a full-color-control mode to control the color of the integral lighting load (e.g., as determined by an x-chromaticity coordinate and a y-chromaticity coordinate).

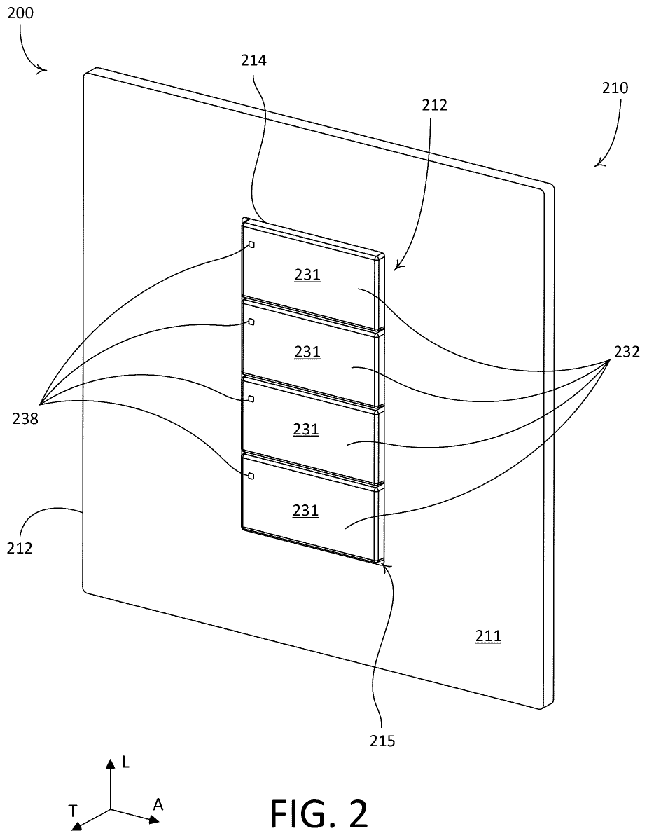

FIGS. 2-10 depict an example control device 200 that may be configured for use in a load control system for controlling one or more load control devices and/or electrical loads, such as lighting loads, motorized window treatments, or the like. For example, the control device 200 may be deployed as the dimmer switch 110 and/or the wall-mounted remote control 142 of the load control system 100. The control device 200 may be configured to be mounted to a wall (e.g., directly to a wall) and/or to an electrical wallbox (e.g., as will be described in greater detail below). The control device 200 may be configured to be electrically connected to a power source (e.g., the power source 102) for receiving power (e.g., when the control device 200 is mounted to the electrical wallbox). In some examples, the control device 200 may also be electrically connected to a communication link (e.g., a wired communication link) for transmitting and/or receiving messages (e.g., digital messages). In addition, the control device 200 may be configured to transmit and/receive messages in wireless signals (e.g., radio-frequency signals, such as the RF signals 108) via a wireless communication link. The control device 200 may be configured to transmit messages including control data for controlling (e.g., indirectly controlling) electrical loads. For example, the control device 200 may be configured to transmit messages including the commands for controlling electrical loads to one or more load control devices (e.g., the dimmer switch 110, the LED driver 120, and/or the controllable light source 130) for controlling respective electrical loads (e.g., the lighting load 112, the LED light source 122, and/or the LED light source of the controllable light source 130). In some examples, the control device 200 may comprise an internal load control circuit for controlling (e.g., directly controlling) electrical loads (e.g., that are electrically coupled to the control device 200). For example, the control device 200 may be configured to control the internal load control circuit to turn the electrical loads on and off, and/or to control an amount of power delivered to the electrical loads.

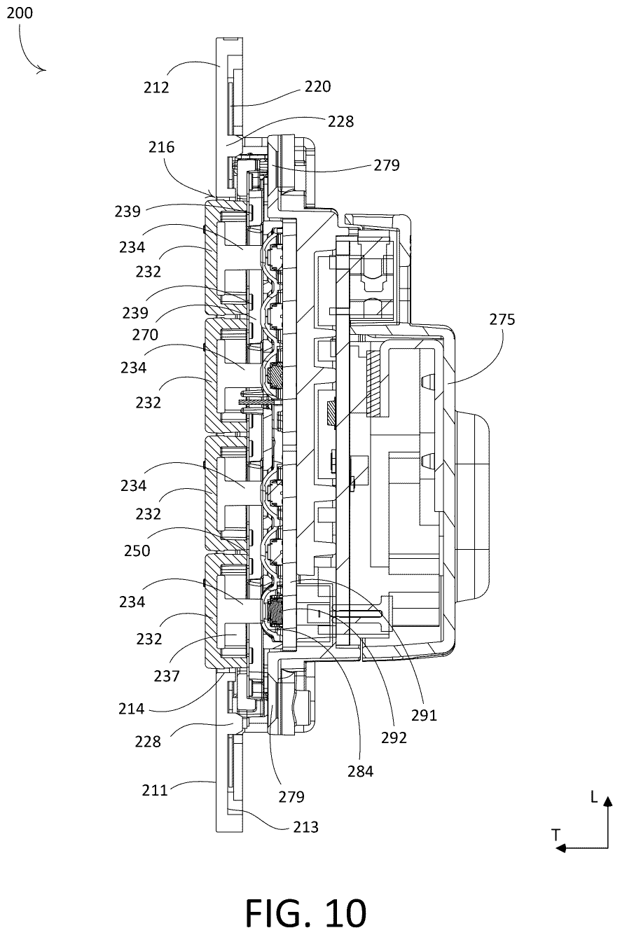

The control device 200 may include a cover plate assembly 210 (e.g., a faceplate assembly), a button assembly 230, and a control module 260. The cover plate assembly 210 may be configured to be attached to (e.g., releasably attached to) the control module 260. It should be appreciated that releasably, as used herein, may be interchangeable with removably. The cover plate assembly 210 may include a cover plate 212 (e.g., a faceplate and/or a wall plate) and an adapter 220. For example, the cover plate 212 may be a decorative cover plate (e.g., an aesthetic element of the control device 200). The button assembly 230 may include a plurality of buttons 232, a button frame 240, and a button carrier 250. The cover plate assembly 210 and the button assembly 230 may be part of an assembly 205 (e.g., a user interface assembly). The control device 200 (e.g., the control module 260) may be configured to be mounted to (e.g., installed within) an electrical wallbox. For example, the control device 200 may be configured to be mounted to a standard round electrical wallbox (e.g., which may be commonly used in countries of the European Union) and/or a standard square wallbox (e.g., which may be commonly used in the United Kingdom). The assembly 205 may be configured to be attached (e.g., releasably attached) to the control module 260. For example, the cover plate assembly 210 may be configured to be attached to the control module 260 with the button assembly 230 located (e.g., captured) between the cover plate assembly 210 and the control module 260 (e.g., as shown in FIG. 10).

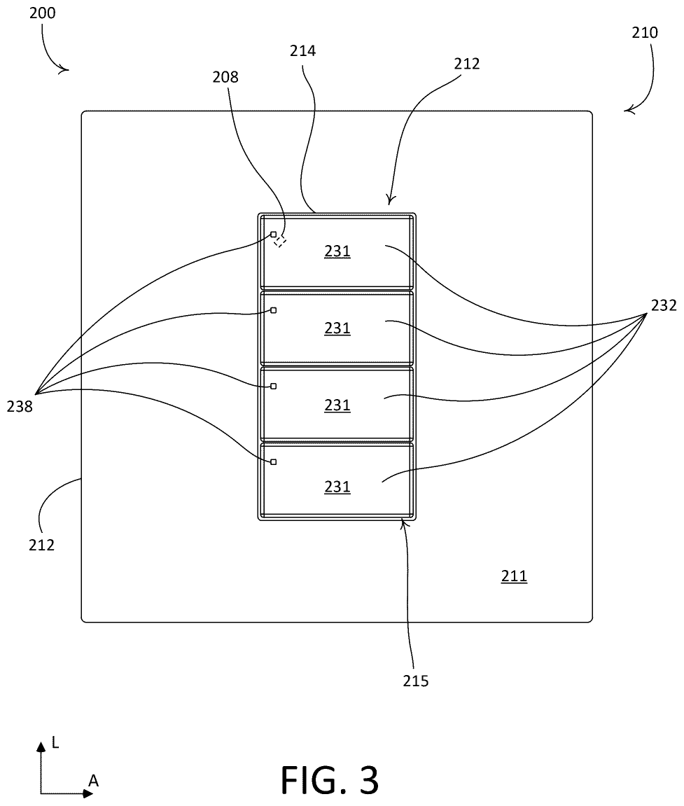

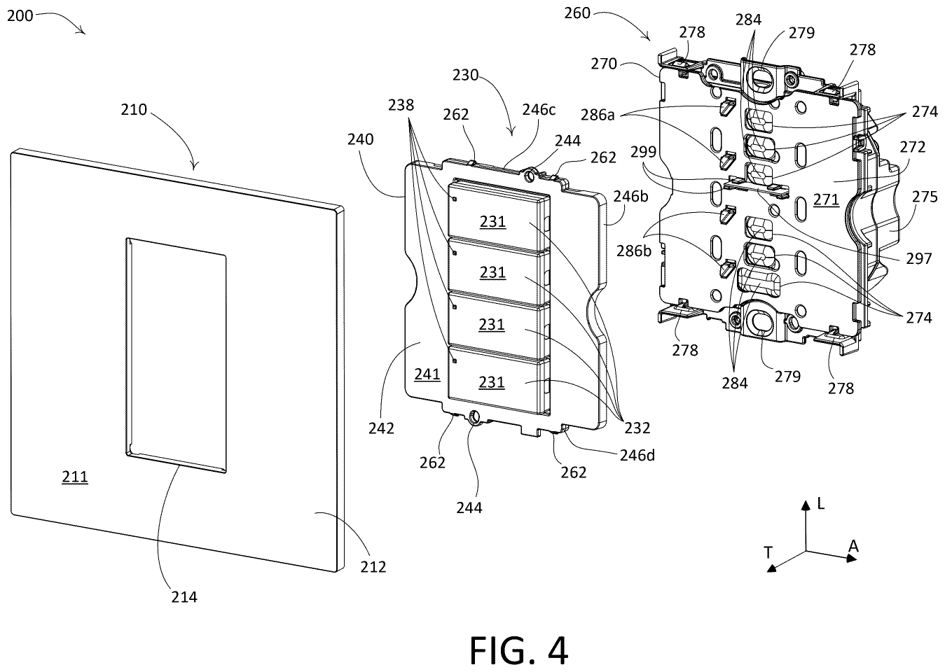

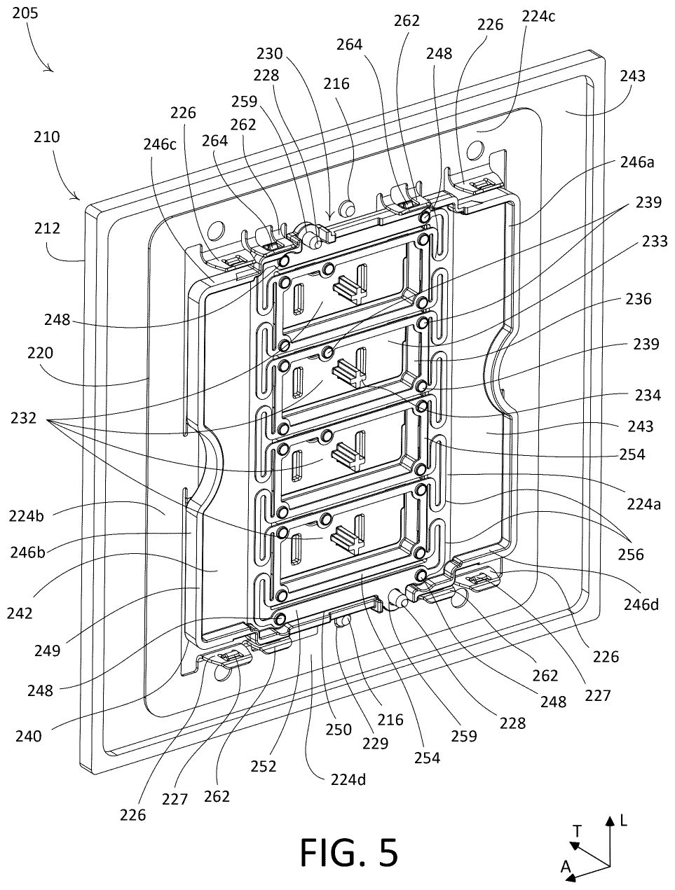

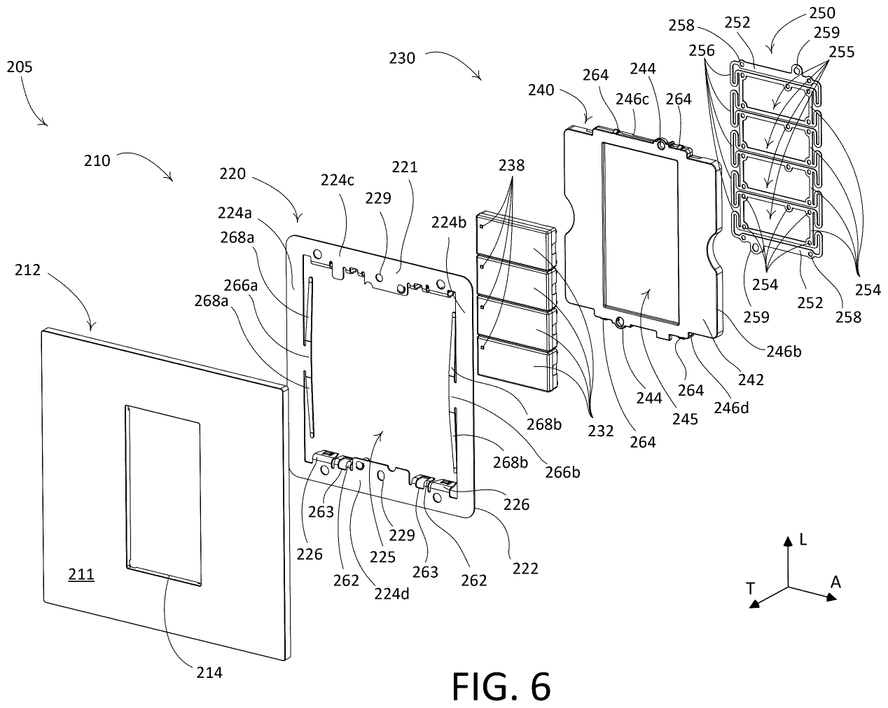

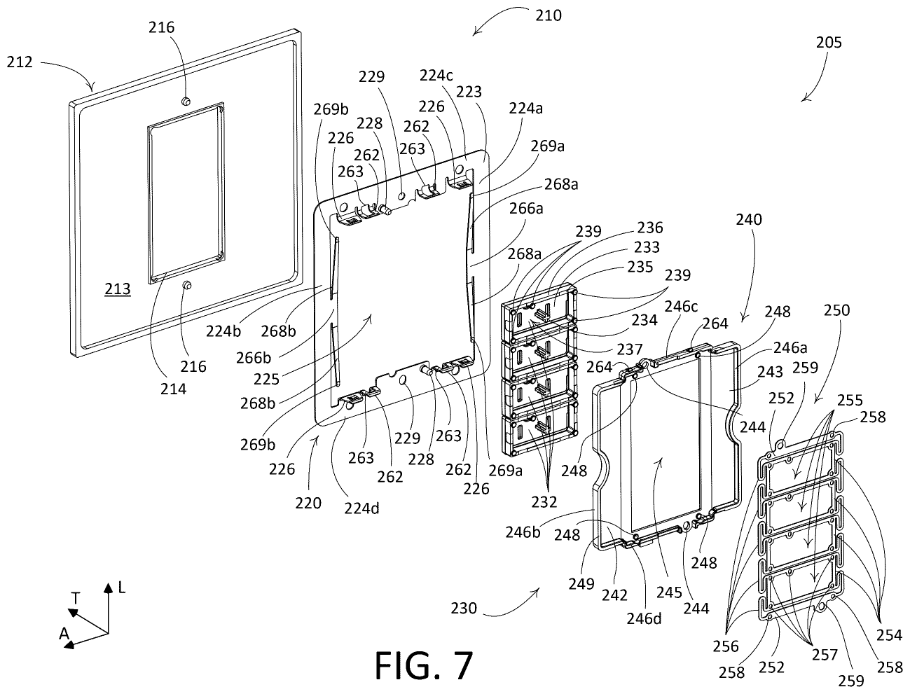

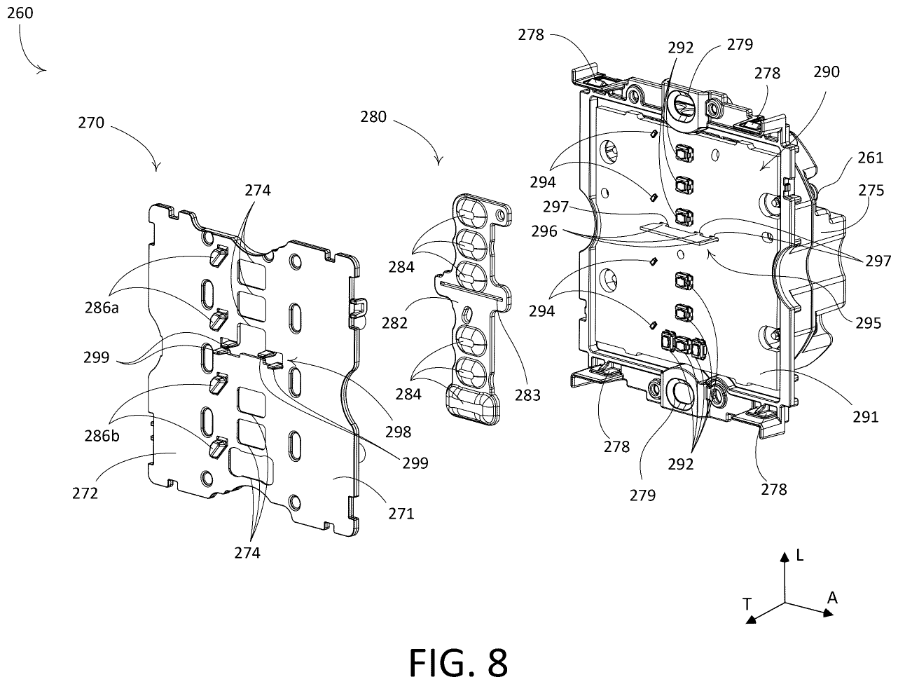

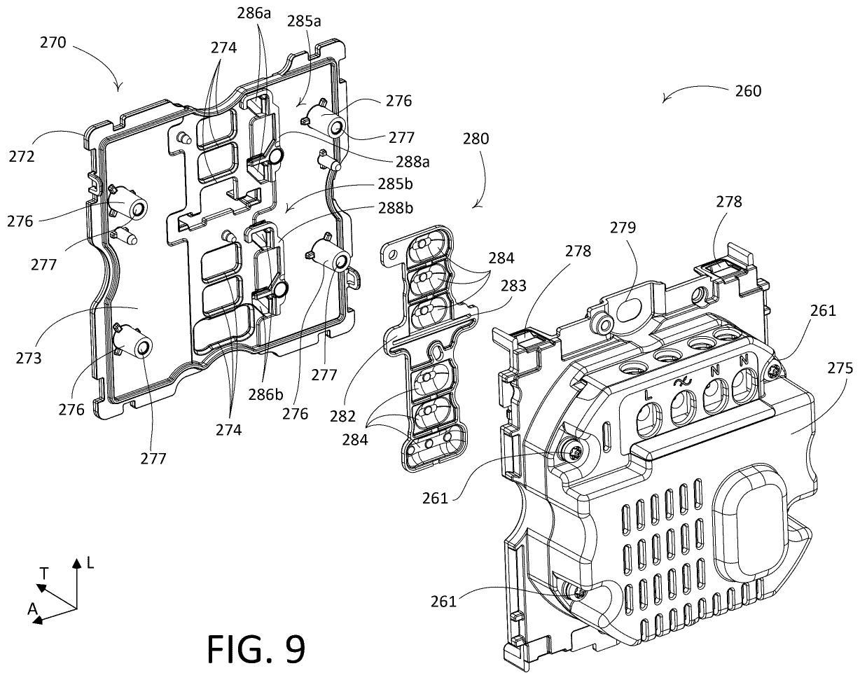

FIG. 2 is a front perspective view and FIG. 3 is a front view of the example control device 200. FIG. 4 is a front exploded view of the control device 200 with the cover plate assembly 210 and the button assembly 230 detached from the control module 260. FIG. 5 is a rear perspective view of the cover plate assembly 210 and the button assembly 230 (e.g., removed from the control module 260). FIG. 6 is a front exploded view and FIG. 7 is a rear exploded view of the cover plate assembly 210 and the button assembly 230 (e.g., removed from the control module 260). FIG. 8 is a front exploded view and FIG. 9 is a rear exploded perspective view of the control module 260. FIG. 10 is a side cross-section view of the control device 200.

The cover plate 212 of the cover plate assembly 210 may define a front surface 211, a rear surface 213, and an opening 214 that extends therethrough. The cover plate 212 may extend in a longitudinal direction L and a lateral direction A. The opening 214 may be configured to at least partially receive a portion of each of the buttons 232. For example, as shown in FIGS. 2 and 3, the control device 200 (e.g., the button assembly 230) may comprise a single column of the buttons 232. The opening 214 may be sized to receive the buttons 232 such that a gap 215 is defined between inner edges of the opening 214 and corresponding outer peripheral surfaces of the buttons 232. The buttons 232 may be configured such that the gap 215 remains substantially uniform around the perimeter of the opening 214.

The cover plate 212 and the buttons 232 may be made of the same material, or may be constructed using the same mix of materials (e.g., metal and/or plastic). Alternatively, the cover plate 212 and the buttons 232 may be made of different materials. In accordance with an example implementation of the control device 200, the buttons 232 may be made of a clear material (e.g., translucent or transparent plastic) and may have veneers that are attached thereto and are made of an opaque material (e.g., opaque plastic), and the cover plate 212 may be made of the metal. While the control device 200 shown in FIGS. 2-10 includes four buttons 232 that are rectangular in shape and of the same size, it should be appreciated that the control device 200 is not limited to having the buttons 232 with illustrated geometries. For example, the control device 200 may alternatively include more or fewer buttons having the same or different geometries and/or sizes.

In some examples, the cover plate 212 may include one or more posts 216 that extend rearward (e.g., in a transverse direction T) from the rear surface 213 of the cover plate 212. As shown, the posts 216 may be cylindrical and may be on opposed sides (e.g., top and bottom) of the opening 214. The posts 216 may be configured to align the adapter 220 to the cover plate 212. For example, the posts 216 may be configured to align the adapter 220 on the rear surface 213 of the cover plate 212. The adapter 220 may define a support frame 222 (e.g., an outer frame) having first and second side portions 224a, 224b, a top portion 224c, and a bottom portion 224d. The first and second side portions 224a, 224b of the support frame 222 may extend between the top portion 224c and the bottom portion 224d. The support frame 222 (e.g., the first and second side portions 224a, 224b, the top portion 224c, and the bottom portion 224d) may have a front surface 221 and a rear surface 223. The support frame 222 (e.g., the first and second side portions 224a, 224b, the top portion 224c, and the bottom portion 224d) may define an opening 225 (e.g., an adapter opening). The opening 225 of the adapter 220 may be configured to enable portions of each of the buttons 232 to extend therethrough. The adapter 220 may define holes 229 in the support frame 222. Each of the holes 229 may be configured to receive one of the posts 216, for example, to align the adapter 220 on the rear surface 213 of the cover plate 212. In some examples, the posts 216 may be omitted.

The adapter 220 may be secured to the cover plate 212 (e.g., to the rear surface 213 of the cover plate 212). For example, the front surface 221 of the adapter 220 may be secured to the rear surface 213 of the cover plate 212 using an adhesive (e.g., double-sided tape) or some other method. In addition, when the cover plate 212 is made from metal, the posts 216 may be, for example, formed as rivets, which may be received through the respective holes 229 in the adapter 220 and deformed (e.g., as part of a riveting process) to attach the adapter 220 to the rear surface 213 of the cover plate 212. Further, when the cover plate 212 is made from plastic, the posts 216 may be, for example, stakes that may be received through the respective holes 229 in the adapter 220 and deformed (e.g., heated and/or melted as part of a heat-staking process) to attach the adapter 220 to the rear surface 213 of the cover plate 212. For example, the adapter 220 (e.g., the support frame 222) may be a single piece attached to the rear surface 213 of the cover plate 212. In some examples, the adapter 220 (e.g., the support frame 222) may comprise multiple pieces attached to the rear surface 513 of the cover plate 212 (e.g., the first and second side portions 224a, 224b, the top portion 224c, and the bottom portion 224d may be separate pieces).

The adapter 220 may be configured to releasably secure the cover plate assembly 210 and the button assembly 230 (e.g., the assembly 205) to the control module 260. The adapter 220 may define a plurality of tabs 226 (e.g., four tabs 226 as shown in FIG. 5) that are configured to secure (e.g., releasably secure) the cover plate assembly 210 and the button assembly 230 to the control module 260. The tabs 226 may extend from the support frame 222 of the adapter 220, for example, proximate to the opening 225. For example, the tabs 226 may extend from the support frame 222 at the top and bottom portions 224c, 224d of the support frame 222 that define the opening 225. The tabs 226 may extend rearward, for example, away from the cover plate 212 (e.g., in the transverse direction T). Each of the tabs 226 may comprise a respective projection 227 (e.g., as shown in FIG. 5). The projections 227 of the tabs 226 may be configured to engage with corresponding features on the control module 260, for example, to hold the cover plate assembly 210 against the control module 260. When the cover plate assembly 210 is attached to the control module 260 (e.g., via the tabs 226), the button assembly 230 may be located (e.g., captured) between the cover plate assembly 210 and the control module 260. In some examples, the tabs 226 may be integral with the cover plate 212 and may extend from the rear surface 213 of the cover plate 212.

The adapter 220 may further comprise one or more posts 228 extending from the rear surface 223 of the adapter 220 (e.g., in the transverse direction T). The posts 228 of the adapter 220 may be configured to align the button assembly 230 to the cover plate assembly 210 (e.g., as will be described in greater detail below). In some examples, the posts 228 may be integral with the cover plate 212 and may extend from the rear surface 213 of the cover plate 212.

Each of the buttons 232 may define a front surface 231, a rear surface 233, and an outer surface 235. The outer surface 235 of each of the buttons 232 may be defined by walls 236 that extend from the rear surface 233. For example, the walls 236 and the rear surface 233 of each of the buttons 232 may define a cavity 237. Each of the buttons 232 may include a post 234 that extends from the rear surface 233 (e.g., in the transverse direction T), for example, through the cavity 237. The posts 234 of the buttons 232 may be configured to actuate respective switches (e.g., respective mechanical tactile switches, such as the switches 292 shown in FIG. 8) when the respective buttons 232 are actuated (e.g., pressed in the transverse direction T), for example by a user of the control device 200. The post 234 of each of the buttons 232 may define a cross-shaped cross-section, as shown. It should be appreciated that although the figures show the post 234 of each of the buttons 232 with the cross-shaped cross-section, the post 234 may define alternately shaped cross-section, for example, such as rectangular, square, circular, etc. Each of the buttons 232 may define a plurality of studs 239 that extend from the outer surface 235 (e.g., in the transverse direction T). The studs 239 may be cylindrical as shown in the drawings. The studs 239 may be configured to secure each of the buttons 232 to the button carrier 250.

Each of the buttons 232 may include a visible indicator 238. The buttons 232 may each be opaque. The visible indicators 238 may be translucent or transparent areas of the front surfaces 231 of the respective buttons 232. Each of the visible indicators 238 may indicate a status of an electrical load that may be controlled in response to actuations of the respective button 232. For example, each of the visible indicators 238 may be indicative of one or more functions that are invoked by depressing the respective buttons 232. Although not shown in the figures, it should be appreciated that one or more of the buttons 232 and/or the visible indicators 238 may include one or more visual representations of a function associated the respective button 232, such as, for example, one or more alphanumeric characters, icons, etc. in any combination.

The buttons 232 may be backlit by respective light sources in the control module 260, for example, one or more light-emitting diodes (LEDs) (e.g., such as light-emitting diodes 294 shown in FIG. 8). Illumination from the one or more light emitting diodes may shine through the respective visible indicator 238 of the respective button 232, but may not shine through the opaque portions of the respective button 232 such that the respective visible indicator 238 is illuminated relative to surrounding opaque portions of the respective button 232.

The button frame 240 may be configured to align the respective front surfaces 231 of the buttons 232 relative to the front surface 211 of the cover plate 212. The button frame 240 may be configured to support the button carrier 250 and to surround the buttons 232. The button frame 240 may be configured to cover the control module 260 (e.g., when the cover plate assembly 210 and the button assembly 230 are connected to the control module 260). The button frame 240 may define a plate portion 242 having a front surface 241 and a rear surface 243. The button frame 240 may define an opening 245 extending through the plate portion 242 (e.g., from the front surface 241 to the rear surface 243). For example, the opening 245 may be configured to receive the buttons 232 such that the opening 245 surrounds the buttons 232. The button frame 240 may comprise first and second side walls 246a, 246b, a top wall 246c, and a bottom wall 246d. The button frame 240 may comprise a rear surface 249 defined by the first and second side walls 246a, 246b, the top wall 246c, and the bottom wall 246d.

The button frame 240 may define a plurality of studs 248 that extend from the rear surface 243 of the button frame 240 (e.g., in the transverse direction T). The studs 248 may be cylindrical as shown in the drawings. The studs 248 may be configured to secure the button carrier 250 to the button frame 240. The button frame 240 may define holes 244 that are located at a top wall 246c and the bottom wall 246d of the button frame 240. The holes 244 may be configured to receive the posts 228 of the adapter 220. The holes 244 and the posts 228 may be configured to align (e.g., in the longitudinal direction L and the lateral direction A) the button assembly 230 with the cover plate assembly 210. The button frame 240 may include a plurality of projections 264 on the top wall 246c and the bottom wall 246d of the button frame 240.

The button carrier 250 may be configured to align respective outer surfaces of the buttons 232 relative to one another. The button carrier 250 may be configured to flex when each of the buttons 232 is pressed and return to its original shape after the respective button 232 is pressed and released. The button carrier 250 may comprise support bars 252 at the top and bottom of the button carrier 250, and a plurality of button frames 254 (e.g., four button frames) located between the support bars 252. Each of the button frames 254 may be configured to support and align a respective one of the plurality of buttons 232. The button frames 254 may be connected to each other and to the support bars 252 by respective spring members 256, which may allow the button carrier 250 to flex. Each of the button frames 254 may define a respective opening 255. Each of the openings 255 may enable the post 234 of the respective button 232 to extend therethrough and abut a respective switch of the control module 260. Each of the openings 255 may also enable light from a respective light source on the control module 260 to be directed toward the visible indicator 238 of the respective button 232. The button carrier 250 may define a plurality of holes 257, 258 therethrough. Each of the holes 257 may be configured to receive one of the studs 239 of the respective buttons 232. For example, each of the studs 239 defined by the respective buttons 232 may be configured to be secured within a respective one of the holes 257. Each of the holes 258 may be configured to receive the studs 248 of the button frame 240. For example, each of the studs 248 defined by the button frame 240 may be configured to be secured within a respective one of the holes 258. The button carrier 250 may define holes 259 that are configured to receive the posts 228 of the adapter 220. The holes 244, 259 of the button frame 240 and the button carrier 250, respectively, and the posts 228 of the adapter 220 may align (e.g., in the longitudinal direction L and the lateral direction A) the button assembly 230 with the cover plate assembly 210.

As shown in FIGS. 8 and 9, the control module 260 may comprise an enclosure having a front enclosure portion 270 and a rear enclosure portion 275. The control module 260 may further comprise a rubber membrane 280 and a printed circuit board assembly 290, which may be enclosed by the front and rear enclosure portions 270, 275. For example, the front enclosure portion 270 may be configured to cover the printed circuit board assembly 290. The front enclosure portion 270 may define a plate portion 272 having a front surface 271, a rear surface 273, and plurality of openings 274 (e.g., extending between the front and rear surfaces 271, 273 of the plate portion 272). The front enclosure portion 270 may further comprise a plurality of drums 276 (e.g., cylindrical drums) extending (e.g., in the transverse direction T) from the rear surface 273 the plate portion 272. The front enclosure portion 270 may be connected (e.g., attached) to the rear enclosure portion 275 via fasteners 261 (e.g., screws) received through openings 277 in the drums 276 of the front enclosure portion 270 and corresponding openings (not shown) in the rear enclosure portion 275.

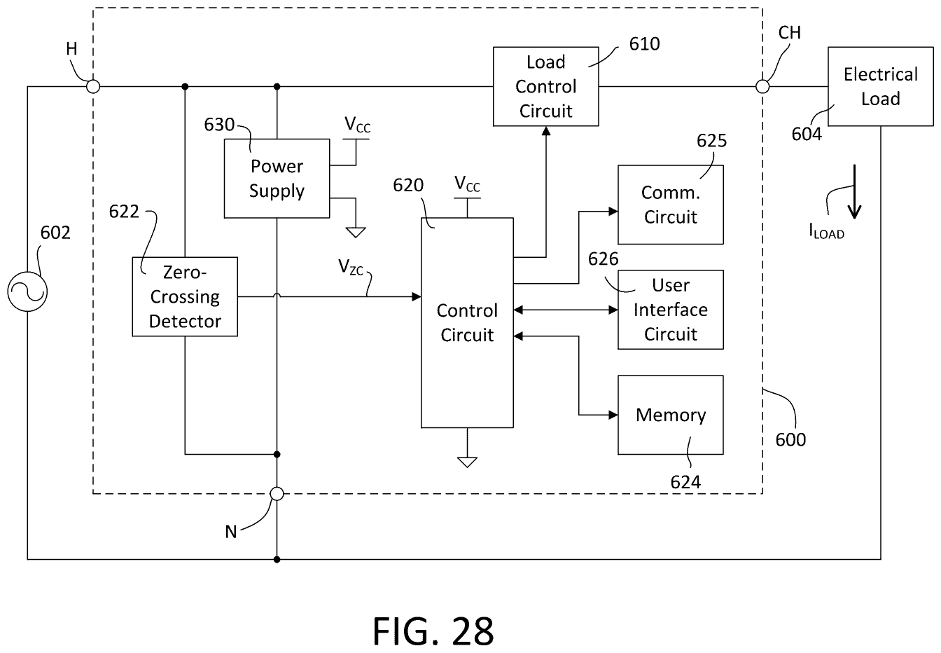

The control module 260 (e.g., the printed circuit board assembly 290) may comprise a first printed circuit board 291 that is located (e.g., secured) between the front enclosure portion 270 and the rear enclosure portion 275. For example, the front enclosure portion 270 and the rear enclosure portion 275 may house (e.g., enclose) control circuitry of the control device 200. The control circuitry of the control device 200 (e.g., the printed circuit board assembly 290) may include a control circuit (e.g., such as control circuit 620 shown in FIG. 28) and/or a communication circuit (e.g., such as communication circuit 625 shown in FIG. 28) mounted to the first printed circuit board 291. For example, the communication circuit may be a wireless communication circuit. The rear enclosure portion 275 may be configured to be installed within a structure. For example, the rear enclosure portion 275 may be configured to be mounted to (e.g., installed within) a standard electrical wallbox via fasteners (e.g., screws-not shown) received via openings 279 in the rear enclosure portion 275.

The control module 260 (e.g., the printed circuit board assembly 290) may include a plurality of switches 292 (e.g., mechanical tactile switches). The plurality of switches 292 may be mounted to the first printed circuit board 291. Each of the switches 292 may be actuated by pressing a respective one of the buttons 232 of the button assembly 230. For example, each of the buttons 232 may be configured to actuate a respective one of the switches 292. The control module 260 (e.g., the printed circuit board assembly 290) may include a plurality of light sources, such as light-emitting diodes 294. Each of the light-emitting diodes 294 may be associated with and located behind a respective one of the buttons 232.

The rear enclosure portion 275 of the control module 260 may include a plurality of clips 278. The projection 227 of each of the tabs 226 of the adapter 220 may be configured to engage a respective one of the clips 278 of the rear enclosure portion 275 of the control module 260. For example, the clips 278 and the tabs 226 may be configured to releasably secure the cover plate assembly 210 (e.g., and the button assembly 230) to the control module 260.

The rubber membrane 280 may be configured to return each of the buttons 232 to an idle position when the respective switches 292 are actuated by pressing and releasing the respective buttons 232. The rubber membrane 280 may define a body 282 and a plurality of dome pads 284. The dome pads 284 may be concave and configured to deform when a force is exerted thereon. The dome pads 284 may be configured to return to the original concave form when the force is removed. Each of the dome pads 284 may be aligned with one or more of the switches 292. At least a portion of the dome pads 284 may extend through the openings 274 of the front enclosure portion 270. When one of the buttons 232 is pressed (e.g., in the transverse direction T), the post 234 of the respective button 232 may extend through the respective opening 274 to depress the respective dome pad 284 and actuate the respective switch 292 mounted to the first printed circuit board 291.

The control module 260 may include one or more light pipe assemblies 285a, 285b. Each of the light pipe assemblies 285a, 285b may comprise multiple light pipes 286a, 286b, respectively (e.g., two light pipes on each of the light pipe assemblies 285a, 285b). The light pipes 286a, 286b of each of the light pipe assemblies 285a, 285b may be configured to direct light from one of the light-emitting diodes 294 to a respective one of the buttons 232 (e.g., to illuminate a respective one of the visible indicators 238 on the respective button 232). For example, each of the light pipe assemblies 285a, 285b may comprise a respective coupling portion 288a, 288b. The coupling portions 288a, 288b of the light pipe assemblies 285a, 285b may be located against the rear surface 273 of the front enclosure portion 270 (e.g., between the front enclosure portion 270 and the light-emitting diodes 294 on the first printed circuit board 291). The light pipes 286a, 286b of the light pipe assemblies 285a, 285b may extend through the front enclosure portion 270 and beyond (e.g., from) the front surface 271 of the front enclosure portion 270 (e.g., towards the buttons 232).

The light-emitting diodes 294 on the first printed circuit board 291 may not be aligned with (e.g., located immediately behind) the visible indicators 238 of the respective buttons 232. For example, FIG. 3 illustrates a location 208 of the respective light-emitting diode 294 behind the top one of the buttons 232 as a dashed line. The light pipes 286a, 286b of each of the first and second light pipe assemblies 285a, 285b may be angled, for example, to direct the light from the light-emitting diodes 294 to the visible indicators 238 of the respective buttons 232. It should be appreciated that although the figures show the visible indicators 238 in the upper left portion of the buttons 232, the visible indicators 238 are not limited to this location and instead could be located in another portion of the buttons 232. And, it should be appreciated that the light pipes 286a, 286b of the light pipe assemblies 285a, 285b may define alternate geometry to direct the illuminate to visible indicators 238 that are located in different areas of the buttons 232.

The control module 260 (e.g., the printed circuit board assembly 290) may include a second printed circuit board 295 having an antenna (not shown) mounted thereto. For example, the antenna of the second printed circuit board 295 may comprise one or more electrical traces formed on the second printed circuit board 295. The antenna of the second printed circuit board 295 may be electrically coupled to the communication circuit (e.g., the wireless communication circuit) mounted for the first printed circuit board 291 and may be configured to transmit and/or receive wireless signals, such as radio-frequency (RF) signals. The second printed circuit board 295 may comprise one or more feet 296 that are configured to be received in respective openings 297 in the first printed circuit board 291 to provide mechanical and electrical connection between the first printed circuit board 291 and the second printed circuit board 295. The rubber membrane 280 may comprise a slot 283 configured to receive the second printed circuit board 295, and the front enclosure portion 270 may comprise a slot 298 configured to receive the second printed circuit board 295. The second printed circuit board 295 may protrude (e.g., in the transverse direction T) from the first printed circuit board 291 and may extend through the slot 283 in the rubber membrane 280 and the slot 298 in the front enclosure portion 270. The front enclosure portion 270 may comprise arms 299 extending from the front surface 271 adjacent to the slot 283 for supporting and/or protecting the second printed circuit board 295. Since the buttons 232 (e.g., and any veneers connected thereto) are made of plastic, the antenna of the second printed circuit board 295 may be configured to transmit the wireless signals through the opening 214 of the cover plate 212.

The control module 260 may be mounted to (e.g., installed to) the electrical wallbox (e.g., at an installation site) when the cover plate assembly 210 and the button assembly 230 are detached from (e.g., not installed on) the control module 260. To facilitate shipping and/or installation of the cover plate assembly 210 and the button assembly 230, the cover plate assembly 210 may be configured to hold (e.g., loosely hold) the button assembly 230 together with the cover plate assembly 210.

The adapter 220 may define a plurality of tabs 262 (e.g., four tabs 262 as shown in FIG. 5) that are configured to secure (e.g., releasably secure) the button assembly 230 to the cover plate assembly 210. Each of the tabs 262 may comprise a respective aperture 263. The tabs 262 may extend from the support frame 222 of the adapter 220 proximate to the opening 225. For example, the tabs 262 may extend from the top and bottom portions 224c, 224d of the support frame 222. It should be appreciated that the tabs 262 may alternatively extend from the side portions 224a, 224b of the support frame 222. The tabs 262 may extend rearward, for example, away from the cover plate 212 (e.g., in the transverse direction T). The aperture 263 of each of tabs 262 may be configured to receive (e.g., engage) a respective one of the projections 264 on the top wall 246c and the bottom wall 246d of the button frame 240 of the button assembly 230, for example, to hold the button assembly 230 against the cover plate assembly 210. When the projections 264 of the button frame 240 are received in the apertures 263 of the respective tabs 262 of the adapter 220, the button assembly 230 may be coupled (e.g., loosely coupled) to the cover plate assembly 210. For example, the apertures 263 may be sized such that there is tolerance in the transverse direction T between the button assembly 230 and the cover plate assembly 210 such that the button assembly 230 is movable in the transverse direction T according to the size of the apertures 263 in the transverse direction T. The one or more posts 228 of the adapter 220 may be configured to align the button assembly 230 to the cover plate assembly 210, for example, when releasably securing the button assembly 230 to the cover plate assembly 210. In some examples, the tabs 262 may be integral with the cover plate 212 and may extend from the rear surface 213 of the cover plate 212.

The cover plate assembly 210 may be configured to hold (e.g., loosely hold) the button assembly 230 together with the cover plate assembly 210 to aide in attaching the cover plate assembly 210 and the button assembly 230 (e.g., the assembly 205) to the control module 260. For example, when the cover plate assembly 210 and the button assembly 230 are detached from the control module 260, a user may mount the control module 260 to the electrical wallbox using fasteners received through the respective openings 279 in the rear enclosure portion 275 and corresponding openings in the electrical wallbox. When the control module 260 is mounted to the electrical wallbox, the user may connect the button assembly 230 to the cover plate assembly 210 by causing the tabs 262 of the adapter 220 to engage the projections 264 on the top and bottom walls 246c, 246d of the button frame 240. The user may then attach the cover plate assembly 210 and the button assembly 230 (e.g., the assembly 205) to the control module 260 mounted to the electrical wallbox by causing the tabs 226 of the adapter 220 to engage the clips 278 of the rear enclosure portion 275 of the control module 260. In some examples, the control module 260 may be shipped to installation site in separate packaging (e.g., in a separate box) than the cover plate assembly 210 and the button assembly 230 (e.g., the assembly 205). In such an example, the cover plate assembly 210 may be configured to hold (e.g., loosely hold) the button assembly 230 together with the cover plate assembly 210 during shipment of the cover plate assembly 210 and the button assembly 230 (e.g., the assembly 205).

The adapter 220 may be configured to align the buttons 232 with the respective switches 292 of the control module 260. When the cover plate assembly 210 is connected to the control module 260, the one or more posts 228 of the adapter 220 may also be configured to align the button assembly 230 with the respective switches 292 of the control module 260 (e.g., in the longitudinal direction L and the lateral direction A). In addition, the adapter 220 may define spring arms 268a, 268b that are configured to align the buttons 232 with respective switches 292 of the control module 260 (e.g., in the transverse direction T). The spring arms 268a, 268b may be resiliently biased from the support frame 222 of the adapter 220. For example, the springs arms 268a, 268b may be resiliently biased rearward (e.g., in the transverse direction T), for example, away from the cover plate 212 and toward the control module 260. For example, the adapter 220 may define a first pair of spring arms 268a on the first side portion 224a of the adapter 220 and a second pair of spring arms 268a on the second side portion 224b of the adapter 220. The adapter 220 may define first and second flaps 266a, 266b that extend (e.g., in the lateral direction A) from the first and second side portions 224a, 224b of the support frame 222, respectively, and into the opening 225. The spring arms 268a, 268b may extend (e.g., in the longitudinal direction L) from the first and second flaps 266a, 266b. For example, the first pair of spring arms 268a may extend from the first flap 266a and the second pair of spring arms 268b may extend from the second flap 266b.

For example, the first flap 266a may extend proximate to a midpoint of the first side portion 224a of the support frame 222 and the second flap 266b may extend proximate to a midpoint of the second side portion 224b of the support frame 222. Each of the pairs of spring arms 268a, 268b may extend from opposed sides of the first and second flaps 266a, 266b. One spring arm of the first pair of spring arms 268a may extend toward the top portion 224c of the support frame 222 and the other spring arm of the first pair of spring arms 268a may extend toward the bottom portion 224d of the support frame 222. One spring arm of the second pair of spring arms 268b may extend toward the top portion 224c of the support frame 222 and the other spring arm of the second pair of spring arms 268b may extend toward the bottom portion 224d of the support frame 222.

The spring arms 268a, 268b may be configured to abut the plate portion 242 of the button frame 240 as the cover plate assembly 210 (e.g., and the button assembly 230) is pressed into engagement (e.g., in the transverse direction T) with the control module 260. For example, each of the spring arms 268a, 268b may define a respective distal end 269a, 269b that is cantilevered from the respective flap 266a, 266b. The distal ends 269a, 269b of the spring arms 268a, 268b may abut the front surface 241 of the plate portion 242 of the button frame 240 of the button assembly 230 as the cover plate assembly 210 (e.g., and the button assembly 230) is pressed into engagement with the control module 260. When the cover plate assembly 210 is connected (e.g., attached) to the control module 260 (e.g., via the engagement between the tabs 226 of the adapter 220 and the respective clips 278 of the rear enclosure portion 275), the spring arms 268a, 268b may apply a force on the plate portion 242 of the button frame 240 to push the button frame 240 towards the control module 260 (e.g., in the transverse direction T).

Since the engagement between each of the tabs 262 of the adapter 220 and the respective projections 264 of the button frame 240 is a loose coupling, the button frame 240 may be configured to move up against the front enclosure portion 270 of the control module 260, such that the rear surface 249 of the button frame 240 may contact the front enclosure portion 270. While the rear surface 249 of the button frame 240 is pushed against the front enclosure portion 270 by the spring arms 268a, 268b, the buttons 232 may be located (e.g., aligned in the transverse direction T) such that the posts 234 of the buttons 232 may contact the respective switches 292 of the control module 260 when the respective buttons 232 are actuated. The spring arms 268a, 268b may deflect independently (e.g., by an independent amount) based on the alignment of the control module 260 within the structure. For example, each of the spring arms 268a, 268b may be configured to deflect different amounts, for example, to enable proper alignment of the buttons 232 with the respective switches on the control module 260 (e.g., in the transverse direction T). For example, each of the spring arms 268a, 268b may enable proper alignment of the plurality of buttons 232 such that a rear surface of each of the posts 234 is aligned (e.g., in a plane that is defined by the transverse direction A and the longitudinal direction L, and is orthogonal to the transverse direction T) with an actuator (e.g., a plunger) of a respective one of the switches 292.

In some examples, the control module 260 of the control device 200 may be mounted to (e.g., installed to) the electrical wallbox at an installation site, such as a building, for example, during constructure of the building. In order to provide control of the electrical loads, which may be controlled by a load control system (e.g., the load control system 100) of the building, it may be desirable to install the button assembly 230 on the control module 260 while construction of the building is ongoing. However, it may be undesirable to install the cover plate assembly 210 on the control module 260 while construction of the building is ongoing (e.g., to protect the cover plate 212, which may be aesthetic element of the control device 200). Accordingly, a temporary cover may be installed on the control module 260 with the button assembly 230 while construction of the building is ongoing.

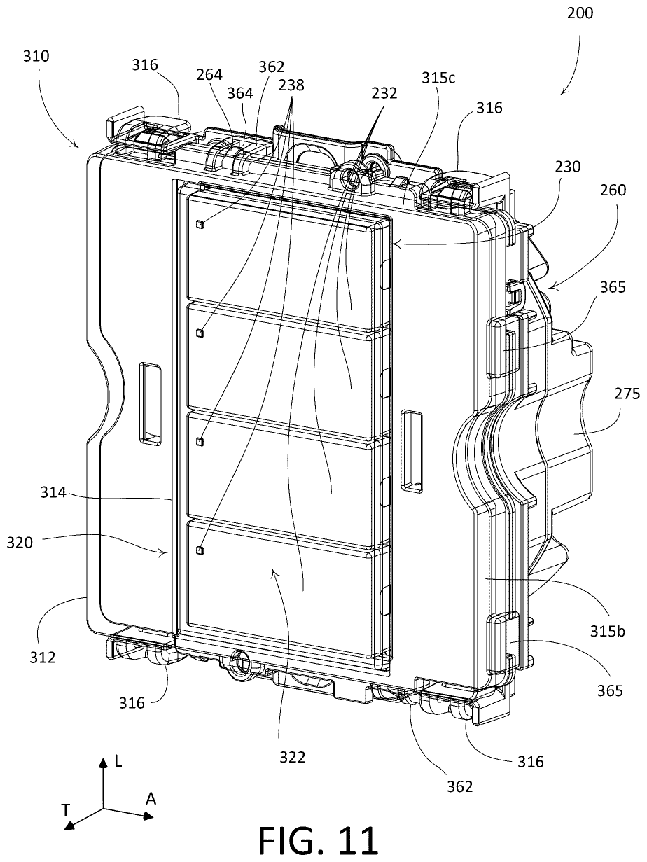

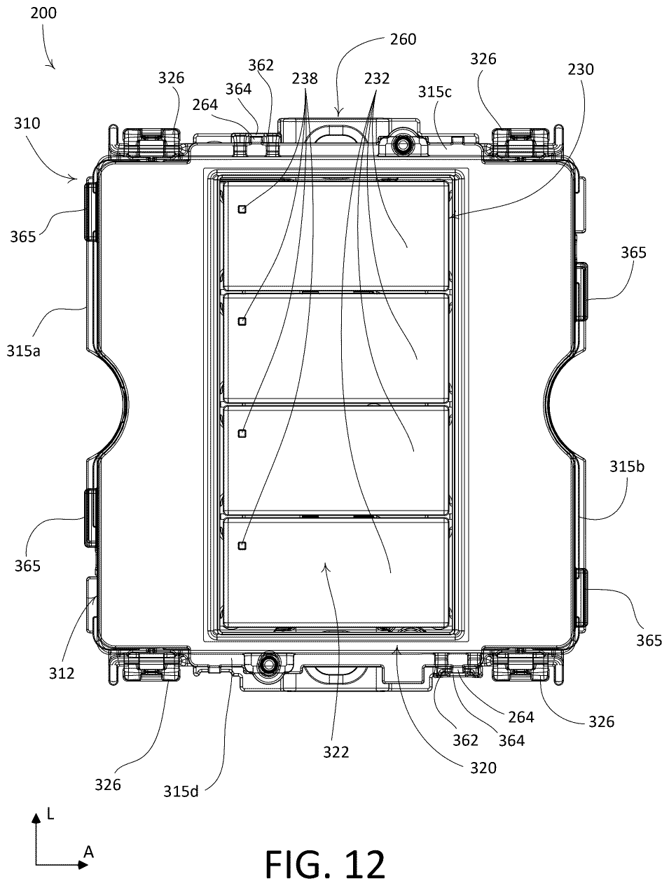

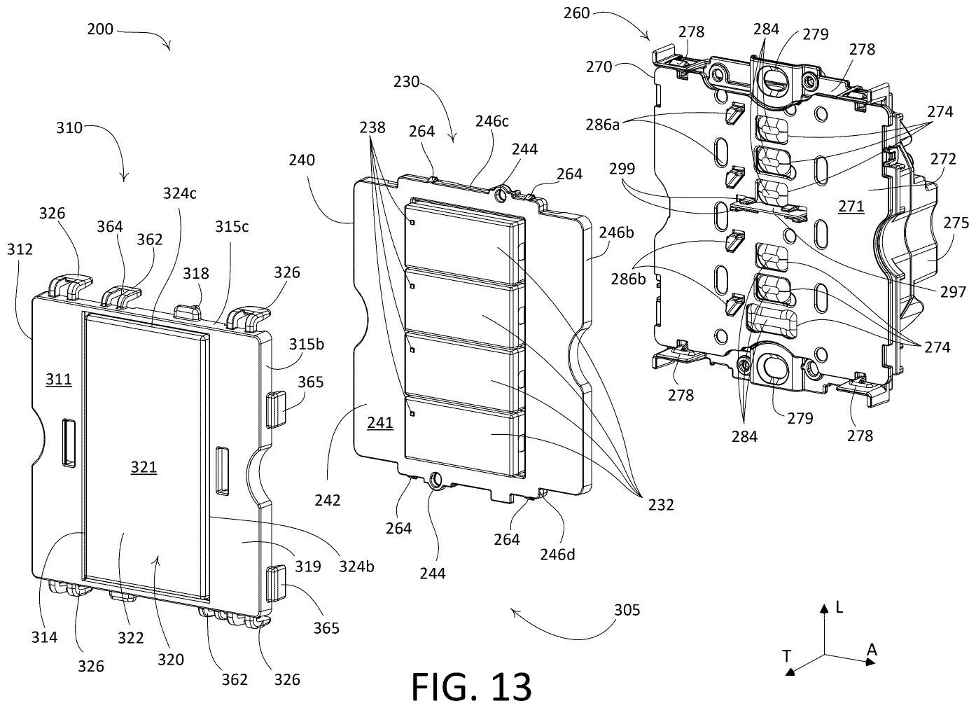

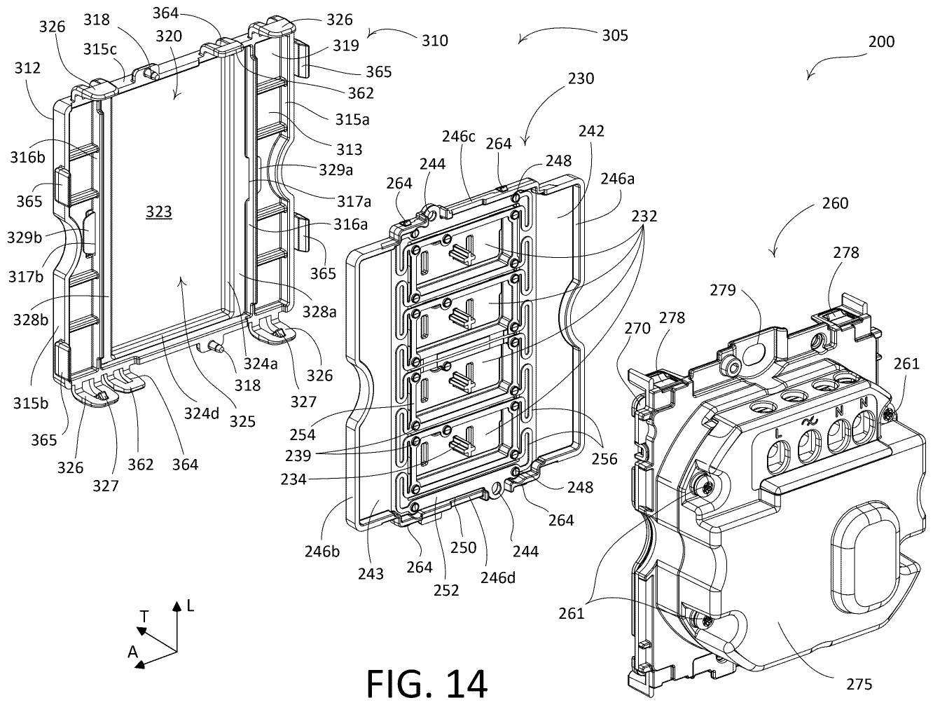

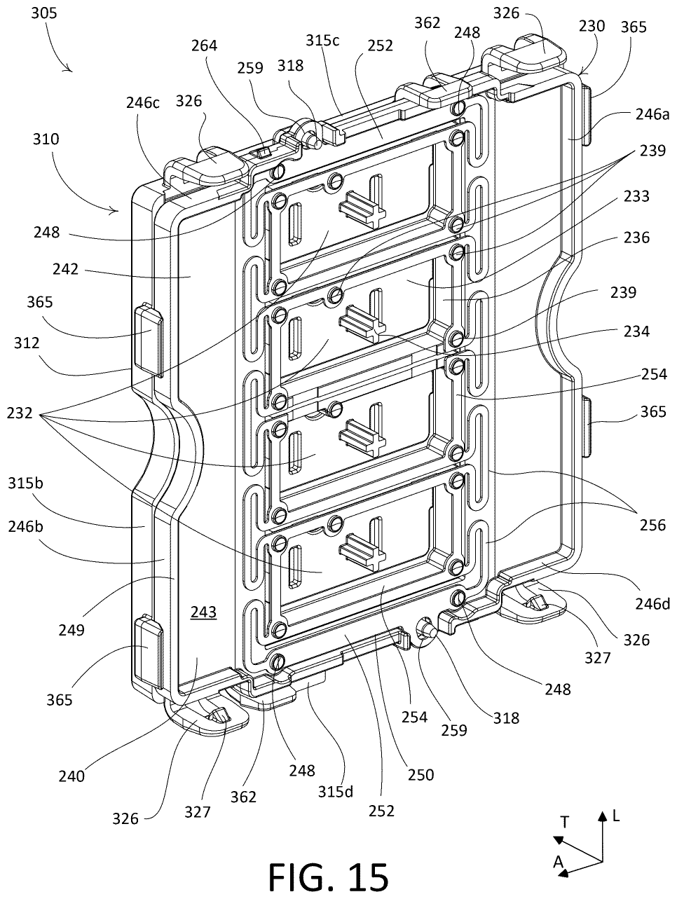

FIG. 11 is a perspective view and FIG. 12 is a front view of the control device 200 with an example temporary cover, such as a cover plate assembly 310 (e.g., a construction cover, a protective cover, and/or a shielding cover) mounted to the control module 260 along with the button assembly 230. FIG. 13 is a front exploded view and FIG. 14 is a rear exploded view of the control device 200 with the cover plate assembly 310 and the button assembly 230 detached from the control module 260. FIG. 15 is a rear perspective view of the cover plate assembly 310 and the button assembly 230 (e.g., removed from the control module 260). The cover plate assembly 310 may include a cover plate 312 and a shell 320 (e.g., a button cover portion).

The cover plate assembly 310 may be configured to be attached (e.g., releasably attached) to the control module 260 with the button assembly 230 located (e.g., captured) between the cover plate assembly 310 and the control module 260. For example, after the control module 260 is mounted to the electrical wallbox, the cover plate assembly 310 and the button assembly 230 may be installed on the control module 260 (e.g., while construction of the building is ongoing) prior to installation of the cover plate assembly 210 (e.g., that has the decorative cover plate 212) onto the control module 260. The cover plate assembly 310 shown in FIGS. 11-15 may be configured to protect the button assembly 230 and/or the control module 260 from damage and/or from exposure to dirt and debris while construction of the building is ongoing. For example, the cover plate assembly 310 may be configured to cover the button assembly 230, the control module 260 (e.g., at least a portion of the control module 260), and one or more openings (e.g., such as the holes 244, the gaps between the buttons 232, and/or the gaps between the buttons 232 and the button frame 240) that extend between the button assembly 230 and the control module 260. The cover plate assembly 310 (e.g., the cover plate 312 and/or the shell 320) may be made of a clear material (e.g., translucent or transparent plastic), such that the button assembly 230 (e.g., the buttons 232) and/or the control module 260 may be visible through the cover plate assembly 310 (e.g., as shown in FIGS. 11 and 12). In some examples, the cover plate 312 may be made from an opaque material and/or covered with an opaque material, such that the buttons 232 (e.g., only the buttons) are visible through the shell 320 of the cover plate assembly 310.

The cover plate 312 may be, for example, a rigid component of the cover plate assembly 310. For example, the cover plate 312 may made of plastic (e.g., polyethylene terephthalate). The cover plate 312 of the cover plate assembly 310 may comprise a body 319 defining a front surface 311, a rear surface 313, and an opening 314 that extends from the front surface 311 to the rear surface 313. The opening 314 in the body 319 of the cover plate 312 may be configured to at least partially receive a portion of each of the buttons 232. The cover plate 312 (e.g., the body 319) may comprise walls (e.g., four walls), such as first and second side walls 315a, 315b, a top wall 315c, and a bottom wall 315d. The first and second side walls 315a, 315b, the top wall 315c, and the bottom wall 315d may extend (e.g., extend rearward) from the rear surface 313 of the body 319 (e.g., in the transverse direction T). The cover plate 312 (e.g., the body 319) may also comprise interior walls 316a, 316b that extend (e.g., extend rearward) from the rear surface 313 of the body 319 (e.g., in the transverse direction T). The interior walls 316a, 316b may be located between the top wall 315c and the bottom wall 315d.

The cover plate 312 may be configured to releasably secure the cover plate assembly 310 and the button assembly 230 to the control module 260. The cover plate assembly 310 and the button assembly 230 may be part of an assembly 305. When the cover plate assembly 310 is attached to the control module 260, the body 319 of the cover plate 312 may cover the button frame 240 of the button assembly 230 and/or the front enclosure portion 270 of the control module 260. For example, the cover plate 312 may be configured to attach to the control module 260 in the same manner as the cover plate 212 of the cover plate assembly 210 attaches to the control module 260 (e.g., via the clips 278). The cover plate 312 may comprise a plurality of tabs 326 (e.g., four tabs as shown in FIG. 15) that are configured to secure (e.g., releasably secure) the cover plate assembly 310 and the button assembly 230 (e.g., the assembly 305) to the control module 260. The tabs 326 may be integral with the cover plate 312 (e.g., as shown in FIGS. 11-15). The tabs 326 may extend rearward, for example, away from the cover plate 312 (e.g., in the transverse direction T). For example, the tabs 326 may extend (e.g., extend rearward) from the top wall 315c and the bottom wall 315d of the cover plate 312. In some examples, the tabs 326 may extend (e.g., extend rearward) from the rear surface 313 of the cover plate 312. Each of the tabs 326 may comprise a respective projection 327 (e.g., as shown in FIG. 15). The projections 327 of the tabs 326 may be configured to engage with the clips 278 of the rear enclosure portion 275 of the control module 260, for example, to hold the cover plate assembly 310 against the control module 260. When the cover plate assembly 310 is attached to the control module 260 (e.g., via the tabs 326), the button assembly 230 may be located (e.g., captured) between the cover plate assembly 310 and the control module 260.

The cover plate 312 may further comprise one or more posts 318 extending from (e.g., proximate to) the top wall 315c and the bottom wall 315d of the cover plate 312 (e.g., in the transverse direction T). The posts 318 of the cover plate 312 may be configured to be received in the holes 244 of the buttons frame 240 and/or the holes 259 in the button carrier 250. The holes 244, 259 of the button frame 240 and the button carrier 250, respectively, and the posts 318 of the cover plate 312 may align (e.g., in the longitudinal direction L and the lateral direction A) the button assembly 230 with the cover plate assembly 310.

The cover plate 312 may be configured to hold (e.g., loosely hold) the button assembly 230 together with the cover plate assembly 310, for example, to aid in attaching the cover plate assembly 310 and the button assembly 230 (e.g., the assembly 305) to the control module 260. For example, the cover plate 312 may be configured to attach to the button assembly 230 in the same manner as the cover plate 212 of the cover plate assembly 210 attaches to the button assembly 230 (e.g., via the projections 264 of the button frame 240). The cover plate 312 may comprise a plurality of tabs 362 (e.g., two tabs 362 as shown in FIG. 15) that are configured to secure (e.g., releasably secure) the button assembly 230 to the cover plate assembly 310. The tabs 362 may be integral with the cover plate 312 (e.g., as shown in FIGS. 11-15). The tabs 362 may extend rearward, for example, away from the cover plate 312 (e.g., in the transverse direction T). For example, the tabs 362 may extend (e.g., extend rearward) from the top and bottom walls 315c, 315d of the cover plate 312. In some examples, the tabs 362 may extend (e.g., extend rearward) from the rear surface 313 of the cover plate 312.

Each of the tabs 362 may comprise a respective aperture 364. The aperture 364 of each of tabs 362 may be configured to receive (e.g., engage) a respective one of the projections 264 on the top wall 246c and the bottom wall 246d of the button frame 240 of the button assembly 230, for example, to hold the button assembly 230 against the cover plate assembly 310. When the projections 264 of the button frame 240 are received in the apertures 364 of the respective tabs 362 of the cover plate 312, the button assembly 230 may be coupled (e.g., loosely coupled) to the cover plate assembly 310. For example, the apertures 364 may be sized such that there is tolerance in the transverse direction T between the button assembly 230 and the cover plate assembly 310 such that the button assembly 230 is movable in the transverse direction T according to the size of the apertures 364 in the transverse direction T. The one or more posts 318 of the cover plate 312 may be configured to align the button assembly 230 to the cover plate assembly 310, for example, when releasably securing the button assembly 230 to the cover plate assembly 310.

The cover plate 312 may further define a plurality of tabs 365 (e.g., four tabs 362 as shown in FIG. 15) that are configured to provide additional support when the button assembly 230 is attached to the cover plate 312. The tabs 365 may be integral with the cover plate 312 (e.g., as shown in FIGS. 11-15). The tabs 365 may extend rearward, for example, away from the cover plate 312 (e.g., in the transverse direction T). For example, the tabs 365 may extend (e.g., extend rearward) from the first and second side walls 315a, 315b of the cover plate 312. When the button assembly 230 is attached to the cover plate 312, the tabs 365 may be configured to contact first and second side walls 246a, 246b of the button frame 240. For example, the tabs 365 may provide a friction fit between the cover plate assembly 310 (e.g., the cover plate 312) and the button assembly 230 (e.g., the button frame 240). Additionally or alternatively, the tabs 365 may be configured to wrap around the button frame 240 of the button assembly 230 such that the tabs 365 engage with a rear surface 249 of the button frame 240, for example, to hold the cover 310 together with (e.g., against) the button assembly 230.

The shell 320 of the cover plate assembly 310 may be configured to be received in the opening 314 of the cover plate 312, such that the shell 320 extends (e.g., in the transverse direction T) beyond the front surface 311 of the cover plate 312. The shell 320 may comprise a flexible sheet 322 (e.g., a flexible membrane) having a front surface 321 and a rear surface 323. The shell 320 may also comprise walls (e.g., four side walls), for example, such as first and second side walls 324a, 324b, a top wall 324c, and a bottom wall 324d. The first and second side walls 324a, 324b, the top wall 324c, and the bottom wall 324d may extend (e.g., extend rearward) from the flexible sheet 322 (e.g., in the transverse direction T), such that the shell 320 defines a recess 325 (e.g., a cavity). The recess 325 may be defined between the flexible sheet 322, the first and second side walls 324a, 324b, the top wall 324c, and the bottom wall 324d. The shell 320 may be, for example, a flexible component of the cover plate assembly 310. The shell 320 (e.g., the flexible sheet 322) may be substantially thin to allow the flexible sheet 322 to be flexible. For example, the flexible sheet 322 of the shell 320 may be characterized by a thickness of approximately 0.10 inches between the front surface 321 and the rear surface 323. The shell 320 may made of, for example, plastic (e.g., polyethylene terephthalate).

When the button assembly 230 is attached to the cover plate assembly 310, the buttons 232 of the button assembly 230 may be configured to extend through the opening 314 in the cover plate 312 and at least partially into the recess 325 defined by the shell 320. The flexible sheet 322 (e.g., the front surface 321) of the shell 320 may be actuated (e.g., pressed) to allow for actuation of one or more of the buttons 232 of the button assembly 230. For example, the front surface 321 of the flexible sheet 322 may define a flexible touch surface of the cover plate assembly 310. When a user actuates the front surface 321 of the flexible sheet 322, the flexible sheet 322 may deform (e.g., flex), such that the rear surface 323 of the flexible sheet 322 (e.g., behind the location of the actuation) may contact the respective front surfaces 231 of one or more of the buttons 232.

The shell 320 may be, for example, a separate component from the cover plate 312 (e.g., the cover plate assembly 310 may be a multi-part assembly). As previously mentioned, the cover plate 312 may be made from a rigid material and the shell 320 may be made from a flexible material. The shell 320 may be received between the interior walls 316a, 316b of the cover plate 312 (e.g., as shown in FIG. 14). The shell 320 may comprise flanges 328a, 328b that extend from the first and second side walls 324a, 324b and towards the interior walls 316a, 316b, respectively (e.g., in the lateral direction A). The flanges 328a, 328b of the shell 320 may be configured to extend adjacent to the rear surface 313 of the cover plate 312. For example, the flanges 328a, 328b of the shell 320 may be configured to abut the rear surface 313 of the cover plate 312 to retain the shell 320 within the opening 314 of the cover plate 312 and to prevent the shell 320 from passing fully through the opening 314 of the cover plate 312. The shell 320 may further comprise wings 329a, 329b that extend from the respective flanges 328a, 328b and through respective slots 317a, 317b (e.g., in the lateral direction A) in the respective interior walls 316a, 316b, for example, to attach the shell 320 to the cover plate 312 and retain the shell 320 within the opening 314 of the cover plate 312. The wings 329A, 329b may extend proximate to a midpoint of the respective flanges 328a, 328b. In some examples, the shell 320 may be formed as part of (e.g., integral with) the cover plate 312, and may be connected to the cover plate 312 at the opening 314 defined by the body 319.

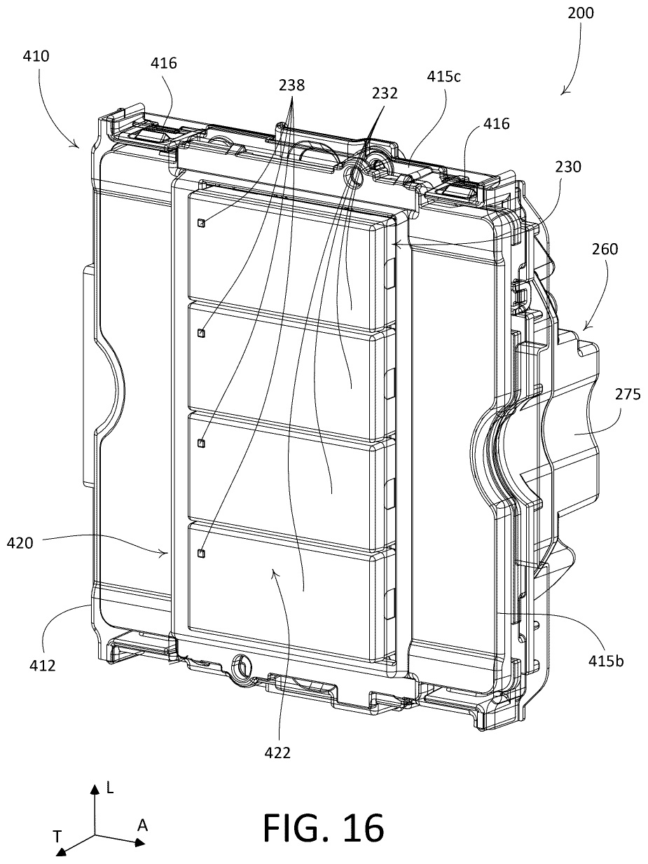

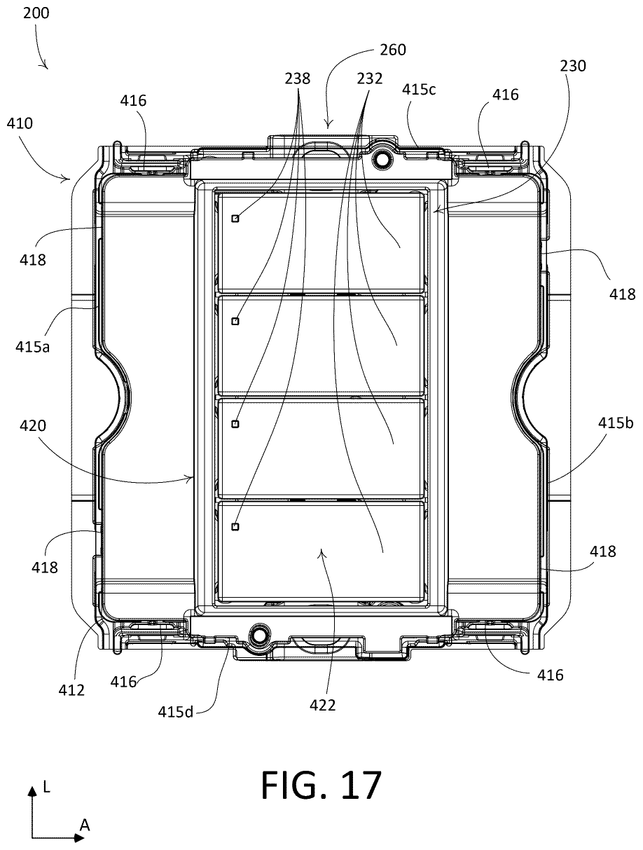

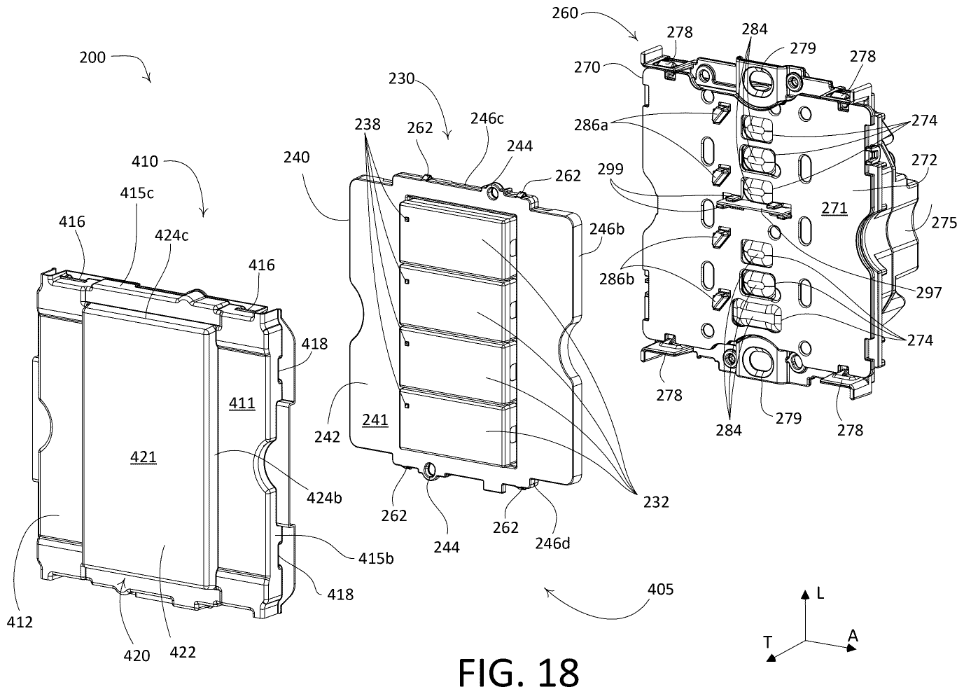

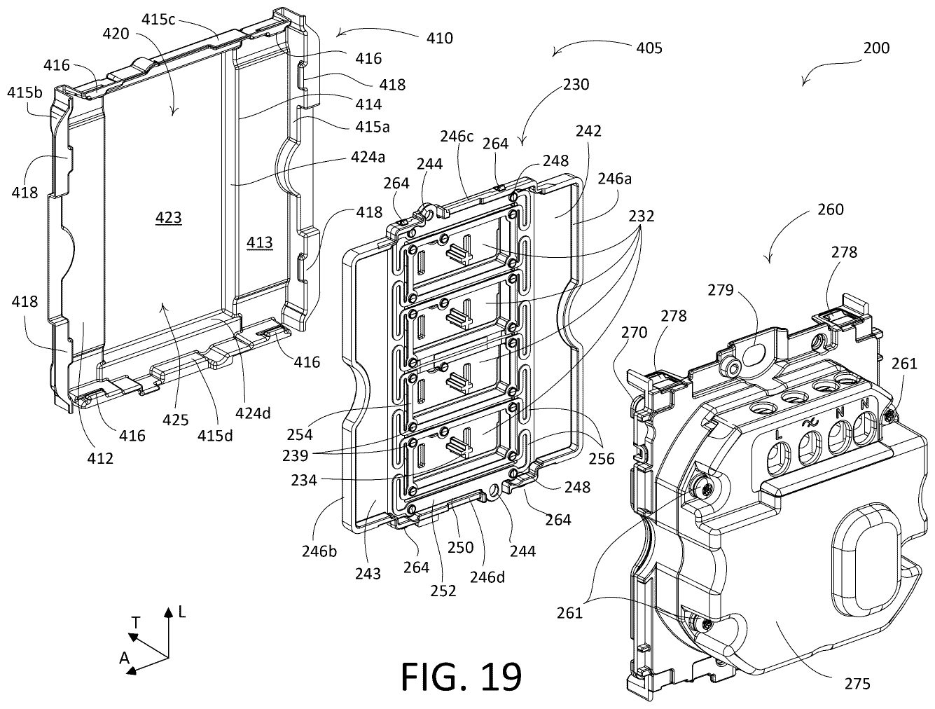

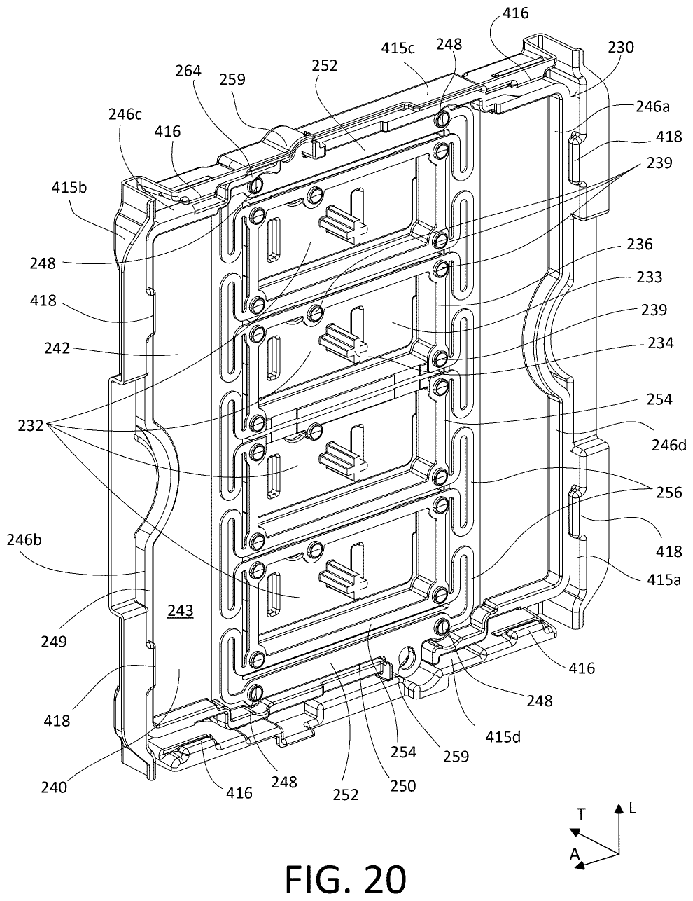

FIG. 16 is a perspective view and FIG. 17 is a front view of the control device 200 with an example temporary cover, such as a cover 410 (e.g., a construction cover and/or a shielding cover) mounted to the control module 260 along with the button assembly 230. FIG. 18 is a front exploded view and FIG. 19 is a rear exploded view of the control device 200 with the cover 410 and the button assembly 230 detached from the control module 260. FIG. 20 is a rear perspective view of the cover 410 and the button assembly 230 (e.g., removed from the control module 260).

The cover 410 may be configured to be attached (e.g., releasably attached) to the control module 260 with the button assembly 230 located (e.g., captured) between the cover 410 and the control module 260. For example, after the control module 260 is mounted to the electrical wallbox, the cover 410 may be installed on the control module 260 (e.g., while construction of the building is ongoing) prior to installation of the cover plate assembly 210 (e.g., that has the decorative cover plate 212) onto the control module 260. The cover 410 shown in FIGS. 16-20 may be configured to protect the button assembly 230 and/or the control module 260 from damage and/or from exposure to dirt and debris while construction of the building is ongoing. For example, the cover 410 may be configured to cover the button assembly 230, the control module 260 (e.g., at least a portion of the control module 260), and/or one or more openings (e.g., such as the holes 244, the gaps between the buttons 232, and/or the gaps between the buttons 232 and the button frame 240) that extend between the button assembly 230 and the control module 260. The cover 410 may be made of a clear material (e.g., translucent or transparent plastic), such that the button assembly 230 (e.g., the buttons 232) and/or the control module 260 may be visible through the cover 410 (e.g., as shown in FIGS. 16 and 17).

The cover 410 may comprise a body 412 defining a front surface 411 and a rear surface 413. The body 412 may further define an opening 414 in the rear surface 413 (e.g., as shown in FIG. 19). The body 412 of the cover 410 may further comprise walls (e.g., four walls), such as, first and second side walls 415a, 415b, a top wall 415c, and a bottom wall 415d. The first and second side walls 415a, 415b, the top wall 415c, and the bottom wall 415d may extend (e.g., extend rearward) from the rear surface 413 of the body 412 (e.g., in the transverse direction T).

The cover 410 (e.g., the body 412) may also comprise a shell 420 (e.g., a button cover portion). The shell 420 of the cover 410 may extend (e.g., in the transverse direction T) from the front surface 411 of the body 412. For example, the shell 420 may meet the body 412 at the opening 414 in the body 412. The shell 420 may comprise a flexible sheet 422 (e.g., a flexible membrane) having a front surface 421 and a rear surface 423. The shell 420 may also comprise first and second side walls 424a, 424b, a top wall 424c, and a bottom wall 424d. The first and second side walls 424a, 424b, the top wall 424c, and the bottom wall 424d may extend (e.g., extend rearward) from the flexible sheet 422 (e.g., in the transverse direction T), such that the shell 420 defines a recess 425 (e.g., a cavity). The recess 425 may be defined between the flexible sheet 422, the first and second side walls 424a, 424b, the top wall 424c, and the bottom wall 424d. The recess 425 defined by the shell 420 may be accessed through the opening 414 defined by the body 412. The first and second side walls 424a, 424b, the top wall 424c, and/or the bottom wall 424d may meet the body 412 at the opening 414 in the body 412.

The cover 410 (e.g., the flexible sheet 422 of the shell 420) may be fabricated to be flexible (e.g., made of a flexible material). The cover 410 (e.g., the flexible sheet 422 of the shell 420) may be substantially thin to allow the flexible sheet 422 to be flexible. For example, the flexible sheet 422 of the shell 420 may be characterized by a thickness of approximately 0.10 inches between the front surface 421 and the rear surface 423. The cover 410 may be made of, for example, plastic (e.g., polyethylene terephthalate). For example, the cover 410 may comprise a single component.

The body 412 may be configured to releasably secure the cover 410 and the button assembly 230 to the control module 260. The cover 410 and the button assembly 230 may be part of an assembly 405. When the cover 410 is attached to the control module 260, the body 412 may cover the button frame 240 of the button assembly 230 and/or the front enclosure portion 270 of the control module 260. For example, the cover plate 312 may be configured to attach to the control module 260 using the clips 278. The body 412 of the cover 410 may comprise a plurality of projections 416 (e.g., four projections as shown in FIG. 20) that are configured to secure (e.g., releasably secure) the cover 410 and the button assembly 230 (e.g., the assembly 405) to the control module 260. The projections 416 may be integral with the body 412. The projections 416 may extend from the top wall 415c and the bottom wall 415d of the body 412. The projections 416 on the top wall 415c may extend downward (e.g., in the longitudinal direction L), and the projections 416 on the bottom wall 415d may extend upward (e.g., in the longitudinal direction L). The projections 416 may be configured to engage with the clips 278 of the rear enclosure portion 275 of the control module 260, for example, to hold the cover 410 against the control module 260. When the cover 410 is attached to the control module 260 (e.g., via the projections 416), the button assembly 230 may be located (e.g., captured) between the cover 410 and the control module 260.

The body 412 may be configured to hold (e.g., loosely hold) the button assembly 230 together with the cover 410. The body 412 of the cover 410 may comprise a plurality of projections 418 (e.g., four projections as shown in FIG. 20) that are configured to secure (e.g., releasably secure) the button assembly 230 to the cover 410. The projections 418 may be integral with the body 412. The projections 418 may extend from the first and second side walls 415a, 415b of the body 412. The projections 418 on the first side wall 415a may extend towards the left (e.g., in the lateral direction A), and the projections 418 on the second side wall 415b may extend towards the right (e.g., in the lateral direction A). When the button assembly 230 is attached to the cover 410, the projections 418 may wrap around the buttons frame 240 of the button assembly 230. The projections 418 may be configured to engage with the rear surface 249 of the button frame 240, for example, to hold the cover 410 together with (e.g., against) the button assembly 230.

When the button assembly 230 is attached to the cover 410, the buttons 232 of the button assembly 230 may be configured to extend into the recess 425 defined by the shell 420. The flexible sheet 422 (e.g., the front surface 421) of the shell 420 may be actuated (e.g., pressed) to allow for actuation of one or more of the buttons 232 of the button assembly 230. For example, the front surface 421 of the flexible sheet 422 may define a flexible touch surface of the cover 410. When a user actuates the front surface 321 of the flexible sheet 322, the flexible sheet 422 may deform (e.g., flex), such that the rear surface 423 of the flexible sheet 422 (e.g., behind the location of the actuation) may contact the respective front surfaces 231 of one or more of the buttons 232.

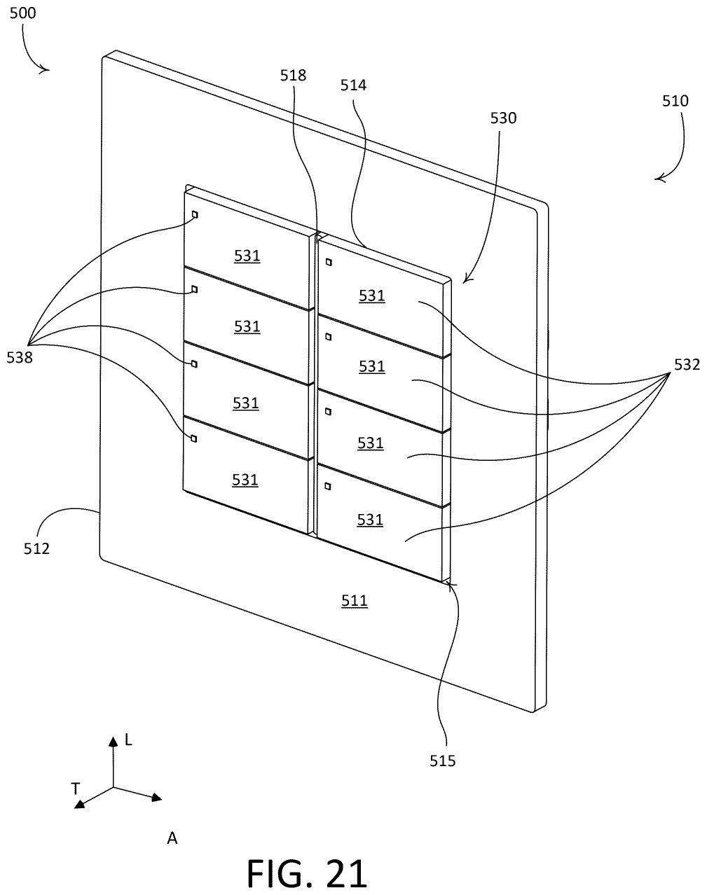

FIGS. 21-27 depict another example control device 500 that may be configured for use in a load control system for controlling one or more load control devices and/or electrical loads, such as lighting loads, motorized window treatments, or the like. For example, the control device 500 may be deployed as the dimmer switch 110 and/or the wall-mounted remote control 142 of the load control system 100. The control device 500 may be configured to be mounted to a wall (e.g., directly to a wall) and/or to an electrical wallbox (e.g., as will be described in greater detail below). The control device 500 may be configured to be electrically connected to a power source (e.g., the power source 102) for receiving power (e.g., when the control device 500 is mounted to the electrical wallbox). In some examples, the control device 500 may also be electrically connected to a communication link (e.g., a wired communication link) for transmitting and/or receiving messages (e.g., digital messages). In addition, the control device 500 may be configured to transmit and/receive messages in wireless signals (e.g., radio-frequency signals, such as the RF signals 108) via a wireless communication link. The control device 500 may be configured to transmit messages including control data for controlling (e.g., indirectly controlling) electrical loads. For example, the control device 500 may be configured to transmit messages including the commands for controlling electrical loads to one or more load control devices (e.g., the dimmer switch 110, the LED driver 120, and/or the controllable light source 130) for controlling respective electrical loads (e.g., the lighting load 112, the LED light source 122, and/or the LED light source of the controllable light source 130). In some examples, the control device 500 may comprise an internal load control circuit for controlling (e.g., directly controlling) electrical loads (e.g., that are electrically coupled to the control device 500). For example, the control device 500 may be configured to control the internal load control circuit to turn the electrical loads on and off, and/or to control an amount of power delivered to the electrical loads.

The control device 500 may include a cover plate assembly 510 (e.g., a faceplate assembly), a button assembly 530, and a control module 560. The cover plate assembly 510 may be configured to be attached to (e.g., releasably attached to) the control module 560. The cover plate assembly 510 may include a cover plate 512 (e.g., a faceplate and/or a wall plate) and an adapter 520. For example, the cover plate 512 may be a decorative cover plate aesthetic element of the control device 500). The button assembly 530 may include a plurality of buttons 532, a button frame 540, and a button carrier 550. The cover plate assembly 510 and the button assembly 530 may be part of an assembly 505 (e.g., a user interface assembly). The control device 500 (e.g., the control module 560) may be configured to be mounted to (e.g., installed within) an electrical wallbox. For example, the control device 500 may be configured to be mounted to a standard round electrical wallbox (e.g., which may be commonly used in countries of the European Union) and/or a standard square wallbox (e.g., which may be commonly used in the United Kingdom). The assembly 505 may be configured to be attached (e.g., releasably attached) to the control module 560. For example, the cover plate assembly 510 may be configured to be attached to the control module 560 with the button assembly 530 located (e.g., captured) between the cover plate assembly 510 and the control module 560 (e.g., in a similar manner as the button assembly 230 is located between the cover plate assembly 210 and the control module 260 as shown in FIG. 10).

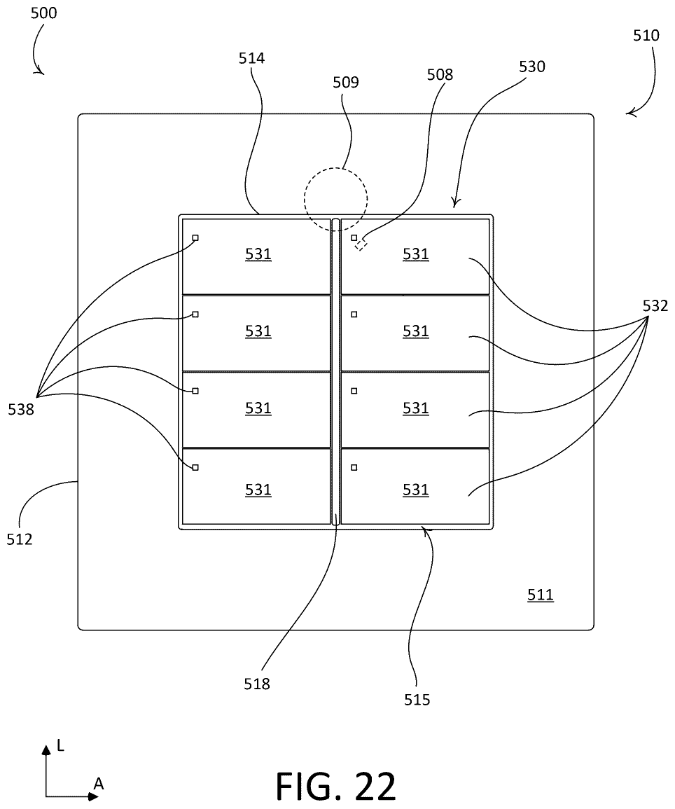

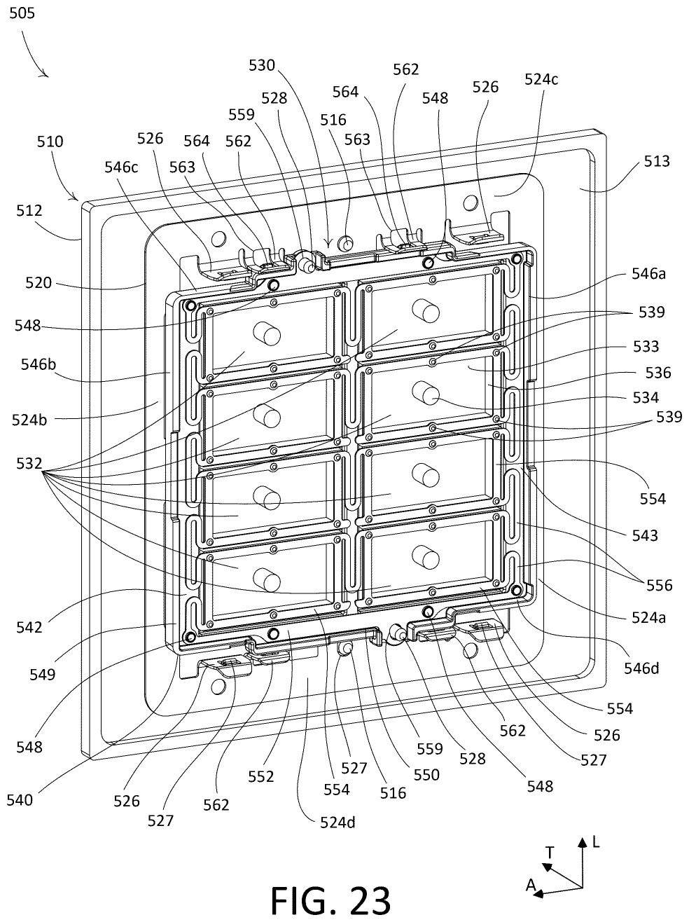

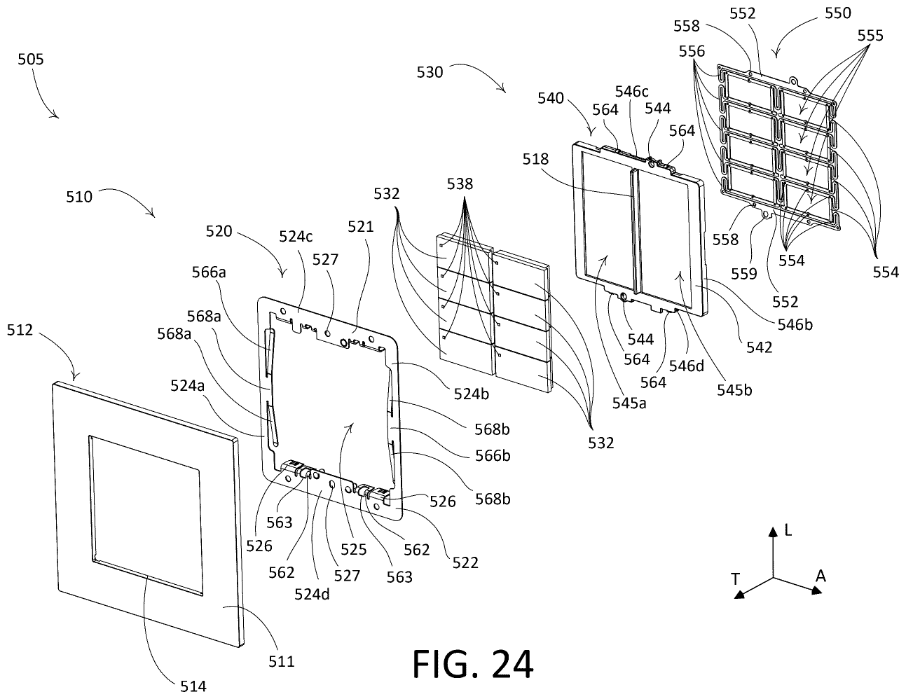

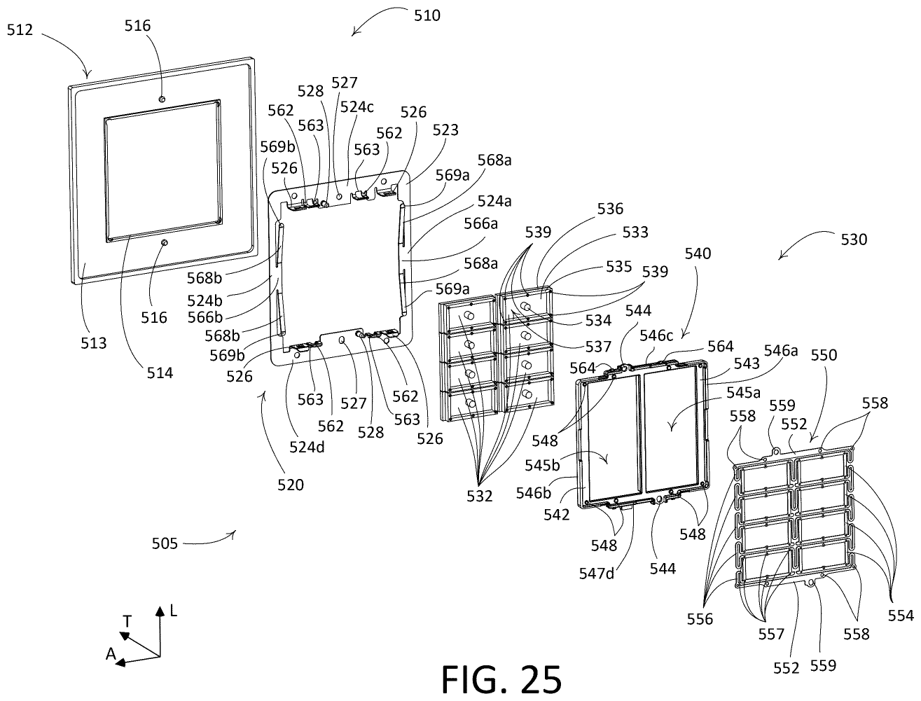

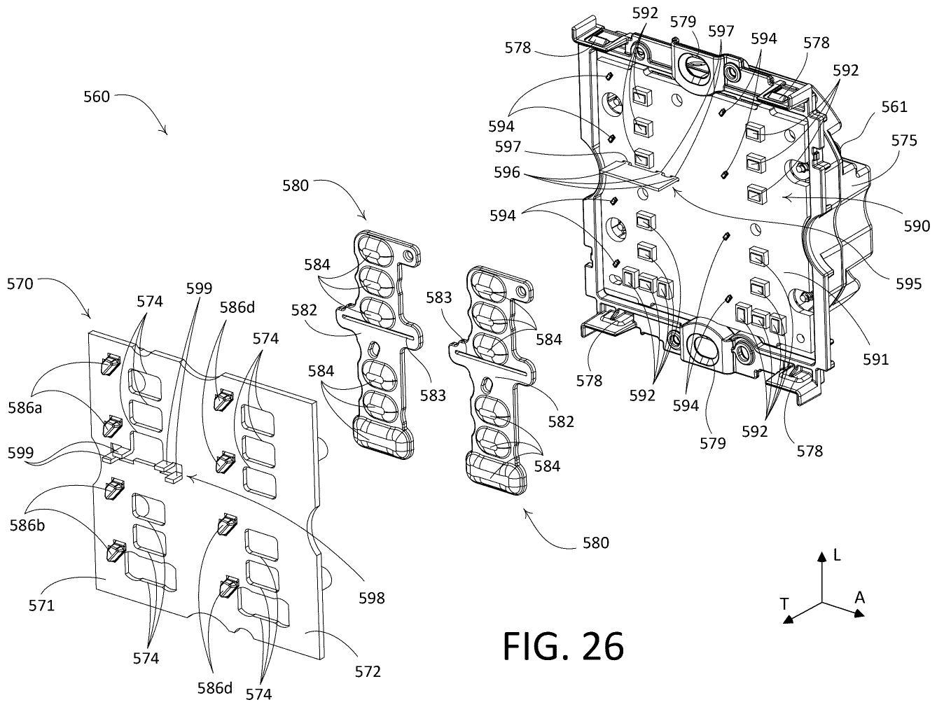

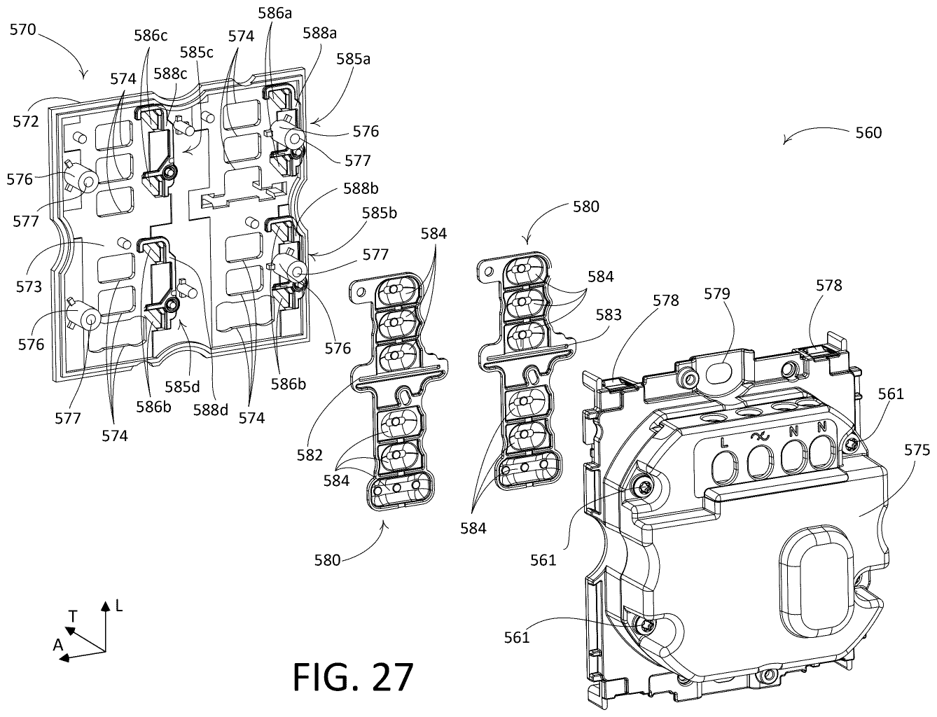

FIG. 21 is a front perspective view of the example control device 500. FIG. 22 is a front view of the example control device 500. FIG. 23 is a rear perspective view of the cover plate assembly 510 and the button assembly 530 (e.g., removed from the control module 560). FIG. 24 is a front exploded view and FIG. 25 is a rear exploded view of the cover plate assembly 510 and the button assembly 530 (e.g., removed from the control module 560). FIG. 26 is a front exploded view and FIG. 27 is a rear exploded view of the control module 560.

The cover plate 512 of the cover plate assembly 510 may define a front surface 511, a rear surface 513, and an opening 514 that extends therethrough. The cover plate 512 may extend in a longitudinal direction L and a lateral direction A. The opening 514 may be configured to at least partially receive a portion of each of the buttons 532. For example, as shown in FIGS. 21 and 22, the control device 500 (e.g., the button assembly 530) may comprise two columns of the buttons 532. In addition, the control device 500 (e.g., the button assembly 530) may comprise a separating portion 518 (e.g., a divider or septum) located between the columns of the buttons 532. The opening 514 of the cover plate 512 may be sized to receive the buttons 532 such that a gap 515 is defined between inner edges of the opening 514 and corresponding outer peripheral surfaces of the buttons 532. The buttons 532 may be configured such that the gap 515 remains substantially uniform around the perimeter of the opening 514.

The cover plate 512 and the buttons 532 may be made of the same material, or may be constructed using the same mix of materials (e.g., metal and/or plastic). Alternatively, the cover plate 512 and the buttons 532 may be made of different materials. In accordance with an example implementation of the control device 500, the buttons 532 may be made of a clear material (e.g., translucent or transparent plastic) and may have veneers that are attached thereto and are made of an opaque material (e.g., opaque plastic), and the cover plate 512 may be made of the metal. While the control device shown in FIGS. 21-27 includes eight buttons 532 that are rectangular in shape and of the same size, it should be appreciated that the control device 500 is not limited to the buttons 166 having the illustrated geometries. For example, the control device 500 may alternatively include more or fewer buttons having the same or different geometries and/or sizes.

In some examples, the cover plate 512 may include one or more posts 516 that extend rearward (e.g., in the transverse direction T) from the rear surface 513 of the cover plate 512. As shown, the posts 516 may be cylindrical and may be on opposed sides (e.g., top and bottom) of the opening 514. The posts 516 may be configured to align the adapter 520 to the cover plate 512. For example, the posts 516 may be configured to align the adapter 520 on the rear surface 513 of the cover plate 512. The adapter 520 may define a support frame 522 (e.g., an outer frame) having first and second side portions 524a, 524b, a top portion 524c, and a bottom portion 524d. The first and second side portions 524a, 524b of the support frame 522 may extend between the top portion 524c and the bottom portion 524d. The support frame 522 (e.g., the first and second side portions 524a, 524b, the top portion 524c, and the bottom portion 524d) may have a front surface 521 and a rear surface 523. The support frame 522 (e.g., the first and second side portions 524a, 524b, the top portion 524c, and the bottom portion 524d) may define an opening 525 (e.g., an adapter opening). The opening 525 of the adapter 520 may be configured to enable portions of each of the buttons 532 to extend therethrough. The adapter 520 may define holes 529 in the support frame 522. Each of the holes 529 may be configured to receive one of the posts 516, for example, to align the adapter 520 on the rear surface 513 of the cover plate 512. In some examples, the posts 516 may be omitted.

The adapter 520 may be secured to the cover plate 512 (e.g., to the rear surface 513 of the cover plate 512). For example, the front surface 521 of the adapter 520 may be secured to the rear surface 513 of the cover plate 512 using an adhesive (e.g., double-sided tape) or some other method. In addition, when the cover plate 512 is made from metal, the posts 516 may be, for example, formed as rivets, which may be received through the respective holes 529 in the adapter 520 and deformed (e.g., as part of a riveting process) to attach the adapter 520 to the rear surface 513 of the cover plate 512. Further, when the cover plate 512 is made from plastic, the posts 516 may be, for example, stakes that may be received through the respective holes 529 in the adapter 520 and deformed (e.g., heated and/or melted as part of a heat-staking process) to attach the adapter 520 to the rear surface 513 of the cover plate 512. For example, the adapter 520 (e.g., the support frame 522) may be a single piece attached to the rear surface 513 of the cover plate 512. In some examples, the adapter 520 (e.g., the support frame 522) may comprise multiple pieces attached to the rear surface 513 of the cover plate 512 (e.g., the first and second side portions 524a, 524b, the top portion 524c, and the bottom portion 524d may be separate pieces).

The adapter 520 may be configured to releasably secure the cover plate assembly 510 and the button assembly 530 (e.g., the assembly 505) to the control module 560. The adapter 520 may define a plurality of tabs 526 that are configured to secure (e.g., releasably secure) the cover plate assembly 510 and the button assembly 530 to the control module 560. The tabs 526 may extend from the support frame 522 of the adapter 520, for example, proximate to the opening 525. For example, the tabs 526 may extend at the top and bottom portions 524c, 524d of the support frame 522 that define the opening 525. It should be appreciated that the tabs 526 may alternatively extend from the side portions 524a, 524b of the support frame 522. The tabs 526 may extend rearward, for example, away from the cover plate 512 (e.g., in the transverse direction T). Each of the tabs 526 may comprise a respective projection 527 (e.g., as shown in FIG. 23). The projections 527 of the tabs 526 may be configured to engage with corresponding features on the control module 560, for example, to hold the cover plate assembly 510 against the control module 560. When the cover plate assembly 510 is attached to the control module 560 (e.g., via the tabs 526), the button assembly 530 may be located (e.g., captured) between the cover plate assembly 510 and the control module 560. In some examples, the tabs 526 may be integral with the cover plate 512 and may extend from the rear surface 513 of the cover plate 512.

The adapter 520 may further comprise one or more posts 528 extending from the rear surface 523 of the adapter 520 (e.g., in a transverse direction T. The posts 528 of the adapter 520 may be configured to align the button assembly 530 to the cover plate assembly 510 (e.g., as will be described in greater detail below). In some examples, the posts 528 may be integral with the cover plate 512 and may extend from the rear surface 513 of the cover plate 512.

Each of the buttons 532 may define a front surface 531, a rear surface 533, and an outer surface 535. The outer surface 535 of each of the buttons 532 may be defined by walls 536 that extend from the rear surface 533. For example, the walls 536 and the rear surface 533 of each of the buttons 532 may define a cavity 537. Each of the buttons 532 may include a post 534 that extends from the rear surface 533 (e.g., in the transverse direction T), for example, through the cavity 537. The posts 534 of the buttons 532 may be configured to actuate respective switches (e.g., respective mechanical tactile switches, such as the switches 592 shown in FIG. 26) when the respective buttons 532 are actuated (e.g., pressed in the transverse direction T), for example by a user of the control device 500. The post 534 of each of the buttons 532 may define a cross-shaped cross-section, as shown. It should be appreciated that although the figures show the post 534 of each of the buttons 532 with the cross-shaped cross-section, the post 534 may define alternately shaped cross-section, for example, such as rectangular, square, circular, etc. Each of the buttons 532 may define a plurality of studs 539 that extend from the outer surface 535 (e.g., in the transverse direction T). The studs 539 may be cylindrical as shown in the drawings. The studs 539 may be configured to secure each of the buttons 532 to the button carrier 550.

Each of the buttons 532 may include a visible indicator 538. The buttons 532 may be opaque. The visible indicators 538 may be translucent or transparent areas of the front surface 531 of the respective buttons 532. Each of the visible indicators 538 may indicate a status of an electrical load that may be controlled in response to actuations of the respective button 532. For example, the visible indicators 538 may be indicative of one or more functions that are invoked by depressing the respective buttons 532. Although not shown in the figures, it should be appreciated that one or more of the buttons 532 and/or the visible indicators 538 may include one or more visual representations of a function associated the respective button 532, such as, for example, one or more alphanumeric characters, icons, etc. in any combination.

The buttons 532 may be backlit by respective light sources in the control module 560, for example, one or more light-emitting diodes (LEDs) (e.g., such as light-emitting diodes 594 shown in FIG. 26). Illumination from the one or more of the light-emitting diodes may shine through the respective visible indicator 538 of the respective button 532, but may not shine through the opaque portions of the respective button 532 such that the respective visible indicator 538 is illuminated relative to surrounding opaque portions of the respective button 532.

The button frame 540 may be configured to align the respective front surfaces 531 of the buttons 532 relative to the front surface 511 of the cover plate 512. The button frame 540 may be configured to support the button carrier 550 and to surround the buttons 532. The button frame 540 may be configured to cover the control module 560 (e.g., when the cover plate assembly 510 and the button assembly 530 are connected to the control module 560). The button frame 540 may define a plate portion 542 having a front surface 541 and a rear surface 543. The button frame 540 may define a first opening 545a and a second opening 545b that both extend through the plate portion 542 (e.g., from the front surface 541 to the rear surface 543). For example, the first opening 545a and the second opening 545b may be configured to receive the buttons 532 such that the openings 545a, 545b surrounds the buttons 532. The button frame 540 may comprise first and second side walls 546a, 546b, a top wall 546c, and a bottom wall 546d. The button frame 540 may comprise a rear surface 549 defined by the first and second side walls 546a, 546b, the top wall 546c, and the bottom wall 546d. The button frame 540 may define the separating portion 518 of the button assembly 530, which may extend from the top wall 546c to the bottom wall 546d of the button frame 540 (e.g., between the two columns of the buttons 532).

The button frame 540 may define a plurality of studs 548 that extend from the rear surface 543 of the button frame 540 (e.g., in the transverse direction T). The studs 548 may be cylindrical as shown in the drawings. The studs 548 may be configured to secure the button carrier 550 to the button frame 540. The button frame 540 may define holes 544 that are located at the top wall 546c and the bottom wall 546d of the button frame 540. The holes 544 may be configured to receive the posts 528 of the adapter 520. The holes 544 and the posts 528 may be configured to align (e.g., in the longitudinal direction L and the lateral direction A) the button assembly 530 with the cover plate assembly 510. The button frame 540 may include a plurality of projections 564 on the top wall 546c and the bottom wall 546d of the button frame 540.

The button carrier 550 may be configured to align respective outer surfaces of the buttons 532 relative to one another. The button carrier 550 may be configured to flex when each of the buttons 532 is pressed and return to its original shape after the respective button 532 is pressed and released. The button carrier 550 may comprise support bars 552 at the top and bottom of the button carrier 550, and a plurality of button frames 554 (e.g., eight button frames 554) located between the support bars 552. Each of the button frames 554 may be configured to support and align a respective one of the plurality of buttons 532. The button frames 554 may be connected to each other and to the support bars 552 by respective spring members 556, which may allow the button carrier 550 to flex. Each of the button frames 554 may define a respective opening 555. Each of the openings 555 may enable the post 534 of the respective button 532 to extend therethrough and abut a respective switch on the control module 560. Each of the openings 555 may also enable light from a respective light source on the control module 560 to be directed toward the visible indicator 538 of the respective button 532. The button carrier 550 may define a plurality of holes 557, 558 therethrough. Each of the holes 557 may be configured to receive one of the studs 539 of the respective buttons 532. For example, each of the studs 539 defined by the respective buttons 532 may be configured to be secured within a respective one of the holes 557. Each of the holes 558 may be configured to receive the studs 548 of the button frame 540. For example, each of the studs 548 defined by the button frame 540 may be configured to be secured within a respective one of the holes 558. The button carrier 550 may define holes 559 that are configured to receive the posts 528 of the adapter 520. The holes 544, 559 of the button frame 540 and the button carrier 550, respectively, and the posts 528 of the adapter 520 may align (e.g., in the longitudinal direction L and the lateral direction A) the button assembly 530 with the cover plate assembly 510.

As shown in FIGS. 26 and 27, the control module 560 may comprise an enclosure having a front enclosure portion 570 and a rear enclosure portion 575. The control module 560 may further comprise rubber membranes 580 (e.g., two rubber membranes) and a printed circuit board assembly 590, which may be enclosed by the first and second enclosure portions 570, 575. For example, the front enclosure portion 570 may be configured to cover the printed circuit board assembly 590. The front enclosure portion 570 may define a plate portion 572 having a front surface 571, a rear surface 573, and plurality of openings 574 (e.g., extending between the front and rear surfaces 571, 573 of the plate portion 572). The front enclosure portion 570 may further comprise a plurality of drums 576 (e.g., cylindrical drums) extending (e.g., in the transverse direction T) from the rear surface 573 of the plate portion 572. The front enclosure portion 570 may be connected (e.g., attached) to the rear enclosure portion 575 via fasteners 261 (e.g., screws) received through openings 577 in the drums 576 of the front enclosure portion 570 and corresponding openings (not shown) in the rear enclosure portion 575.

The control module 560 (e.g., the printed circuit board assembly 590) may comprise a first printed circuit board 591 located (e.g., secured) between the front enclosure portion 570 and the rear enclosure portion 575. For example, the front enclosure portion 570 and the rear enclosure portion 575 may house (e.g., enclose) control circuitry of the control device 500. The control circuitry of the control device 500 (e.g., the printed circuit board assembly 590) may include a control circuit (e.g., such as control circuit 620 shown in FIG. 28) and/or a communication circuit (e.g., such as communication circuit 625 shown in FIG. 28) mounted to the first printed circuit board 591. For example, the communication circuit may be a wireless communication circuit. The rear enclosure portion 575 may be configured to be installed within a structure. For example, the rear enclosure portion 575 may be configured to be mounted to (e.g., installed within) a standard electrical wallbox via fasteners (e.g., screws-not shown) received via openings 579 in the rear enclosure portion 575.

The control module 560 (e.g., the printed circuit board assembly 590) may include a plurality of switches 592 (e.g., mechanical tactile switches). The plurality of switches 592 may be mounted to the first printed circuit board 591. Each of the switches 592 may be actuated by pressing a respective one of the buttons 532 of the button assembly 530. For example, each of the buttons 532 may be configured to actuate a respective one of the switches 592. The control module 560 (e.g., the printed circuit board assembly 590) may include a plurality of light sources, such as light-emitting diodes 594. Each of the light-emitting diodes 594 may be associated with and located behind a respective one of the buttons 532.

The rear enclosure portion 575 of the control module 560 may include a plurality of clips 578. The projection 527 of each of the tabs 526 of the adapter 520 may be configured to engage a respective one of the clips 578 of the rear enclosure portion 575 of the control module 560. For example, the clips 578 and the tabs 526 may be configured to releasably secure the cover plate assembly 510 (e.g., and the button assembly 530) to the control module 560.

The rubber membranes 580 may each be located behind one of the columns of the buttons 532 of the control device 500. The rubber membranes 580 may be configured to return each of the buttons 532 to an idle position when the respective switches 592 are actuated by pressing and releasing the respective buttons 532. Each of the rubber membranes 580 may define a body 582 and a plurality of dome pads 584. The dome pads 584 may be concave and configured to deform when a force is exerted thereon. The dome pads 584 may be configured to return to the original concave form when the force is removed. Each of the dome pads 584 may be aligned with one or more of the switches 592. At least a portion of the dome pads 584 may extend through the openings 574 of the front enclosure portion 570. When one of the buttons 532 is pressed (e.g., in the transverse direction T), the post 534 of the respective button 532 may extend through the respective opening 574 to depress the respective dome pad 584 and actuate the respective switch 592 mounted to the first printed circuit board 591.

The control module 560 may include one or more light pipe structures 585a, 585b, 585c, 585d. Each of the light pipe structures 585a, 585b may comprise multiple light pipes 586a, 586b, 586c, 586d, respectively (e.g., two light pipes on each of the light pipe structures 585a-585d). The light pipes 586a-586d of each of the light pipe structures 585a-585d may be configured to direct light from one of the light-emitting diodes 594 to a respective one of the buttons 532 (e.g., to illuminate a respective one of the visible indicators 538 on the respective button 532). For example, each of the light pipe structures 585a-585d may comprise a respective coupling portion 588a, 588b, 588c, 588d. The coupling portions 588a-588d of the light pipe assemblies 585a-585d may be located against the rear surface 573 of the front enclosure portion 570 (e.g., between the front enclosure portion 570 and the light-emitting diodes 594 on the first printed circuit board 591). The light pipes 586a-586d of the light pipe assemblies 585a-585d may extend through the front enclosure portion 570 and beyond (e.g., from) the front surface 571 of the front enclosure portion 570 (e.g., towards the buttons 532).

The light-emitting diodes 594 on the first printed circuit board 591 may not be aligned with (e.g., located immediately behind) the visible indicators 538 of the respective buttons 532. For example, FIG. 22 illustrates a location 508 of the respective light-emitting diode 594 behind the top button in the right column of the buttons 532 as a dashed line. The locations of the openings 579 in the rear enclosure portion 575 may cause some of the buttons 532 (e.g., the top and bottom buttons) to be partially located in front of the locations of the openings 579 in the rear enclosure portion 575. Since access to the openings 579 in the rear enclosure portion 575 is required to mount the control module 560 to an electrical wallbox, no portions of the control module 560 (e.g., the front enclosure portion 570 and the printed circuit board assembly 590) can cover the openings 579 in the rear enclosure portion 575. In addition, a keepout region 509 in which components may not be mounted to the first printed circuit board 591 (e.g., as indicated by a dashed line in FIG. 22) exists around the openings 579 in the rear enclosure portion 575. Therefore, the light-emitting diode 594 behind the top button in the right column of the buttons 532 must be mounted outside of the keepout region 509 (e.g., at the location 508 indicated with the dashed line in FIG. 22). Since the light-emitting diodes 594 are not aligned with the visible indicators 538 of the respective buttons 532, the light pipes 586a-586d of the first and second light pipe assemblies 585a-585d may be angled, for example, to direct the light from the light-emitting diodes 594 to the visible indicators 538 of the respective buttons 532. It should be appreciated that although the figures show the visible indicators 538 in the upper left portion of the buttons 532, the visible indicators 538 are not limited to this location and instead could be located in another portion of the buttons 532. And, it should be appreciated that the light pipes 586a-586d of the light pipe assemblies 585a-585d may define alternate geometry to direct the illuminate to visible indicators 538 that are located in different areas of the buttons 532.

The control module 560 (e.g., the printed circuit board assembly 590) may include a second printed circuit board 595 having an antenna (not shown) mounted thereto. For example, the antenna of the second printed circuit board 595 may comprise one or more electrical traces formed on the second printed circuit board 595. The antenna of the second printed circuit board 595 may be electrically coupled to the communication circuit (e.g., the wireless communication circuit) mounted for the first printed circuit board 591 and may be configured to transmit and/or receive wireless signals, such as radio-frequency (RF) signals. The second printed circuit board 595 may comprise one or more feet 296 that are configured to be received in respective openings 597 in the first printed circuit board 591 to provide mechanical and electrical connection between the first printed circuit board 591 and the second printed circuit board 595. The rubber membranes 580 may each comprise a slot 583 configured to receive the second printed circuit board 595, and the front enclosure portion 570 may comprise a slot 598 configured to receive the second printed circuit board 595. The second printed circuit board 595 may protrude (e.g., in the transverse direction T) from the first printed circuit board 591 and may extend through the slot 583 in one of the rubber membranes 580 and the slot 598 in the front enclosure portion 570. The front enclosure portion 570 may comprise arms 599 extending from the front surface 571 adjacent to the slot 583 for supporting and/or protecting the second printed circuit board 595. Since the buttons 532 (e.g., and any veneers connected thereto) are made of plastic, the antenna of the second printed circuit board 595 may be configured to transmit the wireless signals through the opening 514 of the cover plate 512.

The control module 560 may be mounted to (e.g., installed to) the electrical wallbox (e.g., at an installation site) when the cover plate assembly 510 and the button assembly 530 are detached from (e.g., not installed on) the control module 560. To facilitate shipping and/or installation of the cover plate assembly 510 and the button assembly 530, the cover plate assembly 510 may be configured to hold (e.g., loosely hold) the button assembly 530 together with the cover plate assembly 510.

The adapter 520 may define a plurality of tabs 562 (e.g., four tabs 562 as shown in FIG. 23) that are configured to secure (e.g., releasably secure) the button assembly 530 to the cover plate assembly 510. Each of the tabs 562 may comprise a respective aperture 563. The tabs 562 may extend from the support frame 522 proximate to the opening 525. For example, the tabs 562 may extend from the top and bottom portions 524c, 524d of the support frame 522. It should be appreciated that the tabs 562 may alternatively extend from the side portions 524a, 524b of the support frame 522. The tabs 562 may extend rearward, for example, away from the cover plate 512 (e.g., in the transverse direction T). The aperture 563 of each of tabs 562 may be configured to receive (e.g., engage) a respective one of the projections 564 on the top wall 546c and the bottom wall 546d of button frame 540 of the button assembly 530, for example, to hold the button assembly 530 against the cover plate assembly 510. When the projections 564 of the button frame 540 are received in the apertures 563 of the respective tabs 562 of the adapter 520, the button assembly 530 may be coupled (e.g., loosely coupled) to the cover plate assembly 510. The one or more posts 528 of the adapter 520 may be configured to align the button assembly 530 to the cover plate assembly 510, for example, when releasably securing the button assembly 530 to the cover plate assembly 510. In some examples, the tabs 662 may be integral with the cover plate 512 and may extend from the rear surface 513 of the cover plate 512.

The cover plate assembly 510 may be configured to hold (e.g., loosely hold) the button assembly 530 together with the cover plate assembly 510 to aide in attaching the cover plate assembly 510 and the button assembly 530 (e.g., the assembly 505) to the control module 560. For example, when the cover plate assembly 510 and the button assembly 530 are detached from the control module 560, a user may mount the control module 560 to the electrical wallbox using fasteners received through the respective openings 579 in the rear enclosure portion 575 and corresponding openings in the electrical wallbox. When the control module 560 is mounted to the electrical wallbox, the user may connect the button assembly 530 to the cover plate assembly 510 by causing the tabs 562 of the adapter 520 to engage the projections 564 on the top and bottom walls 546c, 546d of the button frame 540. The user may then attach the cover plate assembly 510 and the button assembly 530 (e.g., the assembly 505) to the control module 560 mounted to the electrical wallbox by causing the tabs 526 of the adapter 520 to engage the clips 578 of the rear enclosure portion 575 of the control module 560. In some examples, the control module 560 may be shipped to installation site in separate packaging (e.g., in a separate box) than the cover plate assembly 510 and the button assembly 530 (e.g., the assembly 505). In such an example, the cover plate assembly 510 may be configured to hold (e.g., loosely hold) the button assembly 530 together with the cover plate assembly 510 during shipment of the cover plate assembly 510 and the button assembly 530 (e.g., the assembly 505).

The adapter 520 may be configured to align the buttons 532 with the respective switches 592 of the control module 560. When the cover plate assembly 510 is connected to the control module 560, the one or more posts 528 of the adapter 520 may also be configured to align the button assembly 530 with the respective switches 592 of the control module 560 (e.g., in the longitudinal direction L and the lateral direction A). In addition, the adapter 520 may define spring arms 568a, 568b that are configured to align the buttons 532 with respective switches of the control module 560 (e.g., in the transverse direction T). The spring arms 568a, 568b may be resiliently biased from the support frame 522. For example, the springs arms 568a, 568b may be resiliently biased rearward (e.g., in the transverse direction T), for example, away from the cover plate 512 and toward the control module 560. For example, the adapter 520 may define a first pair of spring arms 568a on the first side portion 524a of the adapter 520 and a second pair of spring arms 568b on the second side portion 524b of the adapter 520. The adapter 520 may define first and second flaps 566a, 566a that extend (e.g., in the lateral direction A) from the first and second side portions 524a, 524b of the support frame 522, respectively, and into the opening 525. The spring arms 568a, 568b may extend (e.g., in the longitudinal direction L) from the first and second flaps 566a, 566a. For example, the first pair of spring arms 568a may extend from the first flap 566a and the second pair of spring arms 568b may extend from the second flap 566b.

For example, the first flap 566a may extend proximate to a midpoint of the first side portion 524a of the support frame 522 and the second flap 566b may extend proximate to a midpoint of the second side portion 524b of the support frame 522. Each of the pairs of spring arms 568a, 568b may extend from opposed sides of the first and second flaps 566a, 566a. One spring arm of the first pair of spring arms 568a may extend toward the top portion 524c of the support frame 522 and the other spring arm of the first pair of spring arms 568a may extend toward the bottom portion 524d of the support frame 522. One spring arm of the second pair of spring arms 568b may extend toward the top portion 524c of the support frame 522 bottom portion side 524d of the support frame 522.

The spring arms 568a, 568b may be configured to abut the plate portion 542 of the button frame 540 as the cover plate assembly 510 (e.g., and the button assembly 530) is pressed into engagement (e.g., in the transverse direction T) with the control module 560. For example, each of the spring arms 568a, 568b may define a respective distal end 569a, 569b that is cantilevered from the respective flap 566A, 566B. The distal ends 569a, 569b of the spring arms 568a, 568b may abut the front surface 541 of the plate portion 542 of the button frame 540 of the button assembly 530 as the cover plate assembly 510 (e.g., and the button assembly 530) is pressed into engagement with the control module 560. When the cover plate assembly 510 is connected (e.g., attached) to the control module 560 (e.g., via the engagement between the tabs 526 of the adapter 520 and the respective clips 578 of the rear enclosure portion 575), the spring arms 568a, 568b may apply a force on the plate portion 542 of the button frame 540 to push the button frame 540 towards the control module 560 (e.g., in the transverse direction T).

Since the engagement between each of the tabs 562 of the adapter 520 and the respective projections 564 of the button frame 540 is a loose coupling, the button frame 540 may be configured to move up against the front enclosure portion 570 of the control module 560, such that the rear surface 549 of the button frame 540 may contact the front enclosure portion 570. While the rear surface 549 of the button frame 540 is pushed against the front enclosure portion 570 by the spring arms 568a, 568b, the buttons 532 may be located (e.g., aligned in the transverse direction T) such that the posts 534 of the buttons 532 may contact the respective switches 592 of the control module 560 when the respective buttons 532 are actuated. The spring arms 568a, 568b may deflect independently (e.g., by an independent amount) based on the alignment of the control module 561 within the structure. For example, each of the spring arms 568a, 568b may be configured to deflect different amounts, for example, to enable proper alignment of the buttons 532 with the respective switches on the control module 560. For example, each of the spring arms 568a, 568b may enable proper alignment of the plurality of buttons 532 such that a rear surface of each of the posts 534 is substantially parallel (e.g., in a plane that is defined by the transverse direction A and the longitudinal direction L, and is orthogonal to the transverse direction T) to a front surface of an actuator (e.g., a plunger) of a respective one of the switches 592.

In some examples, the control module 560 of the control device 500 may be mounted to (e.g., installed to) the electrical wallbox at an installation site, such as a building, for example, during constructure of the building. In order to provide control of the electrical loads, which may be controlled by a load control system (e.g., the load control system 100) of the building, it may be desirable to install the button assembly 530 on the control module 560 while construction of the building is ongoing. However, it may be undesirable to install the cover plate assembly 510 on the control module 560 while construction of the building is ongoing (e.g., to protect the cover plate 512, which may be an aesthetic element of the control device 500). Accordingly, a temporary cover may be installed on the control module 560 with the button assembly 530 while construction of the building is ongoing. For example, a cover plate assembly, such as the cover plate assembly 310 shown in FIGS. 11-15 (e.g., but sized for a two-column button assembly) may be installed on the control module 560. In addition, a cover, such as the cover 410 shown in FIGS. 16-20 (e.g., but sized for a two-column button assembly) may be installed on the control module 560.

FIG. 28 is a simplified block diagram of an example control device 600 (e.g., a load control device) that may be deployed as, for example, the control device 200 and/or the control device 500. The control device 600 may be adapted to be coupled in series electrical connection between a power source 602, such as an alternating-current (AC) power source, and an electrical load 604. The control device 600 may include a hot terminal H that may be adapted to be coupled to a hot side of the power source 602 and a controlled-hot terminal CH that may be adapted to be coupled to the electrical load 604. In addition, the control device 600 may also comprise a neutral terminal N that may be adapted to be coupled to a neutral side of the power source 602. In some examples, the power source 602 may comprise a direct-current (DC) power source.

The control device 600 may comprise a load control circuit 610 coupled in series electrical connection between the hot terminal H and the controlled-hot terminal CH and thus coupled in series electrical connection between the power source 602 and the electrical load 604. The load control circuit 610 may be configured to control power delivered to the electrical load 604. For example, the load control circuit 610 may comprise a switching circuit, such as a relay or other suitable switching circuit, for enabling the control device 600 to connect the electrical load 604 to and disconnect the electrical load 604 from the power source 602 to turn the electrical load 604 on and off, respectively. In some examples, the load control circuit 610 may comprise a dimming circuit including a bidirectional semiconductor switch for turning the electrical load 604 on and off and/or adjusting an amount of power delivered to the electrical load. For example, the bidirectional semiconductor switch of the load control circuit 610 may comprise a thyrsistor (e.g., a triac and/or one or more silicon-controlled rectifiers), one or more field-effect transistors (FETs) (e.g., a FET in a full-wave rectifier bridge and/or two FETs in anti-series connection), one or more insulated-gate bipolar transistors (IGBTs), or other suitable bidirectional semiconductor switch.

The control device 600 may comprise a control circuit 620 configured to control the load control circuit 610 to control the power delivered to the electrical load 604, for example, to turn the electrical load 604 on and off. The control circuit 620 may include one or more of a processor (e.g., a microprocessor), a microcontroller, a programmable logic device (PLD), a field programmable gate array (FPGA), an application specific integrated circuit (ASIC), or any suitable controller or processing device. For example, the control circuit 620 may be configured to control the load control circuit 610 to turn the electrical load 604 on and off and/or to adjust the amount of power delivered to the electrical load 604.

The control device 600 may comprise a power supply 630. The power supply 630 may generate a direct-current (DC) supply voltage V_{CC} for powering the control circuit 620 and the other low-voltage circuitry of the control device 600. The power supply 630 may be coupled between the hot terminal H and the neutral terminal N (e.g., across the power source 602). The power supply 630 may be configured to conduct a charging current from the power source 602 to generate the DC supply voltage V_{CC}. In some examples, the power supply 630 may also be coupled between the hot terminal H and the controlled-hot terminal CH (e.g., in parallel with the load control circuit 610), for example, when a connection to the neutral side of the power source 602 is not available. The power supply 630 may be configured to conduct a charging current from the power source 602 to generate the DC supply voltage V_{CC}. In such an example, the power supply 630 may be configured to conduct the charging current through the electrical load 604 to generate the DC supply voltage V_{CC}.

The control device 600 may comprise a zero-crossing detector 622 (e.g., a zero-cross detect circuit) electrically coupled between the hot terminal H and the neutral terminal N (e.g., across the power source 602). In some examples, the zero-crossing detector 622 may also be coupled between the hot terminal H and the controlled-hot terminal CH (e.g., in parallel with the load control circuit 610), for example, when a connection to the neutral side of the power source 602 is not available. The zero-crossing detector 622 may be configured to generate a zero-cross detect signal V_{ZC} that indicates the zero-crossing points of an AC mains line voltage generated by the power source 602. The control circuit 620 may receive the zero-cross detect signal V_{ZC} and may be configured to control the load control circuit 610 based on the zero-cross detect signal V_{ZC} received from the zero-crossing detector 622 (e.g., relative to the zero-crossings of the AC mains line voltage as determined from the zero-cross detect signal V_{ZC}).

The control device 600 may comprise a memory 624 that may be communicatively coupled to the control circuit 620 for the storage and/or retrieval of data. The memory 624 may be implemented as an external integrated circuit (IC) or as an internal circuit of the control circuit 610. The memory 624 may comprise a computer-readable storage media or machine-readable storage media that maintains computer-executable instructions for performing one or more procedures and/or functions as described herein. For example, the memory 624 may comprise computer-executable instructions or machine-readable instructions that when executed by the control circuit 620 configure the control circuit 620 to provide one or more portions of the procedures described herein. The control circuit 620 may access the instructions from the memory 624 for being executed to cause the control circuit 620 to operate as described herein, or to operate one or more other devices as described herein. The memory 624 may comprise computer-executable instructions for executing configuration software. For example, the control circuit 620 may be configured to store in and retrieve from the memory 624 configuration data for configuring the control device 600. In addition, the control circuit 620 may be configured to store in and retrieve from the memory 624 configuration settings and/or operational settings of the control device 600. For example, the operational characteristics stored in the memory 624 may be configured during a configuration procedure of the control device 600.

The control device 600 may comprise a communication circuit 626 configured to communicate (e.g., transmit and/or receive) messages (e.g., digital messages). For example, the communication circuit 626 may comprise one or more wired communication circuits and/or wireless communication circuits. The one or more wired communication circuits and/or wireless communication circuits of the communication circuit 626 may be implemented as external integrated circuits (ICs) or as internal circuits of the control circuit 620. For example, the one or more wireless communication circuits of the communication circuit 626 may include for example, one or more a radio-frequency (RF) transceivers coupled to a respective antenna for transmitting and/or receiving RF signals. In addition, the one or more wireless communication circuits of the communication circuit 626 may also include an RF transmitter for transmitting RF signals, an RF receiver for receiving RF signals, or an infrared (IR) transmitter and/or receiver for transmitting and/or receiving IR signals. The one or more wireless communication circuits of the communication circuit 626 may be capable of performing communication via the same communication channels or different communication channels. In some examples, the communication circuit 626 may be configured to communicate via a network, such as a wireless or wired local area network (LAN), e.g., for access to the Internet. In addition, the communication circuit 626 may be configured to communicate via a control network (e.g., a wired or wireless control communication link). The control circuit 620 may be configured to receive messages including control data (e.g., one or more commands) for controlling the electrical load 604 via the communication circuit 626. In addition, the control circuit 620 may be configured to receive message including, for example, selected presets and/or the statuses of the electrical loads. Further, the control circuit 620 may be configured to transmit messages including feedback data (e.g., such as status information of the control device 600) via the communication circuit 626.

The control device 600 may further comprise a user interface circuit 628. The user interface circuit 628 may comprise one or more input circuits for receiving inputs (e.g., user inputs). For example, the input circuits of the user interface circuit 628 may comprise one or more switches (e.g., the switches 292, 592) configured to be actuated in response to actuation of one or more respective actuators (e.g., buttons) of the control device 600 (e.g., the buttons 232, 532). The control circuit 620 may be configured to generate control data (e.g., one or more commands) for controlling the electrical load 604 in response to the user inputs received via the user interface circuit 628 (e.g., in response to actuations of the switches of the user interface circuit 628). For example, the control circuit 620 may be configured to control the load control circuit 610 to turn the electrical load 604 on and off and/or to adjust the amount of power delivered to the electrical load in response to the user inputs received via the user interface circuit 628. The control circuit may also be configured to transmit messages including the control data (e.g., one or more indications of actuation of the switches and/or commands for controlling the electrical loads) in response to the user inputs received via the user interface circuit 628 for enabling other load control device to control electrical loads. In addition, the control circuit 620 may be configured to configure the control device 600 (e.g., by adjusting the configuration settings and/or operational settings stored in the memory 624) in response to the user inputs received via the user interface circuit 628.

The user interface circuit 628 may also comprise one or more light sources configured to illuminate one or more visible indicators of the control device 600 (e.g., the visible indicators 238, 538) for providing feedback information to a user. For example, the one or more light sources of the user interface circuit 628 may comprise light-emitting diodes (e.g., the light-emitting diodes 292, 592).

What is claimed is:

1. A control device that is configured for use in a load control system for controlling an amount of power delivered to one or more electrical loads, the control device comprising:
a cover plate assembly comprising a cover plate and an adapter attached to a rear surface of the cover plate, the cover plate defining an opening;
a button assembly comprising a button frame and a plurality of buttons supported by the button frame, the plurality of buttons configured to be received within the opening of the cover plate of the cover plate assembly, each of the plurality of buttons defining a rear surface and a post extending from the rear surface; and
a control module comprising a printed circuit board and a plurality of switches mounted to the printed circuit board, each of the plurality of switches configured to be actuated by one of the posts of the plurality of buttons when the respective button is pressed;
wherein the button assembly is configured to be releasably secured to the control module, and wherein the adapter defines a plurality of spring arms that abut the button frame of the button assembly to push the button frame against the control module, and wherein each of the plurality of spring arms are configured to deflect independently in a transverse direction to align the posts of the plurality of buttons with the plurality of switches.

2. The control device of claim 1, wherein the adapter comprises a frame that defines an adapter opening through which the plurality of buttons extend.

3. The control device of claim 2, wherein the adapter defines a plurality of first tabs that extend from the frame proximate to the opening, and wherein the plurality of first tabs are configured to secure the cover plate assembly and the button assembly to the control module.

4. The control device of claim 3, wherein the control module comprises a plurality of clips that are configured to engage the plurality of first tabs.

5. The control device of claim 3, wherein the adapter defines a plurality of second tabs that extend from the frame proximate to the opening, each of the plurality of second tabs defining an aperture.

6. The control device of claim 5, wherein the button frame comprises a plurality of projections on a top side and a bottom side of the button frame.

7. The control device of claim 6, wherein each of the plurality of projections are configured to be received by a respective one of the plurality of second tabs to hold the button assembly against the cover plate assembly.

8. The control device of claim 1, wherein the cover plate comprises one or more posts that extend rearward from the rear surface of the cover plate, the one or more posts configured to align the adapter with the cover plate.

9. The control device of claim 8, wherein the button frame defines a plate portion that surrounds a button frame opening that is configured to receive the plurality of buttons.

10. The control device of claim 9, wherein the plurality of spring arms are configured to abut the plate portion of the button frame as the cover plate assembly is pressed into engagement with the control module.

11. The control device of claim 10, wherein each of the plurality of spring arms are configured to deflect independently based on alignment of the control module with a structure.

12. The control device of claim 10, wherein each of the plurality of spring arms are configured to deflect to enable proper alignment of the plurality of buttons with the plurality of switches such that a rear surface of each of the posts is substantially parallel to a respective one of the switches.

13. The control device of claim 1, wherein the adapter comprises one or more posts extending from a rear surface of the adapter.

14. The control device of claim 13, wherein the one or more posts extending from the rear surface of the adapter are configured to be received by respective openings on the button frame to align the button assembly with the cover plate assembly.

15. The control device of claim 1, wherein the button assembly comprises a button carrier that is configured to align respective outer surfaces of the plurality of buttons relative to one another.

16. The control device of claim 1, wherein the button assembly comprises two columns of buttons with a separating portion located between the two columns of buttons.

17. The control device of claim 1, further comprising a plurality of light sources mounted to the printed circuit board of the control module.

18. The control device of claim 17, wherein each of the plurality of buttons are backlit by a respective one of the plurality of light sources.

19. The control device of claim 18, wherein each of the plurality of buttons comprises an opaque portion and a visible indicator configured to be illuminated by a respective one of the plurality of light sources.

20. The control device of claim 19, further comprising a plurality of light pipe assemblies configured to direct light from the plurality of light sources to the visible indicators on the plurality of buttons.

21. The control device of claim 20, wherein each of the plurality of light pipe assemblies comprises a first portion that defines an angled upper surface that is located within a cavity defined by a respective button of the plurality of buttons to direct the light of a corresponding one of the light sources toward the visible indicator.

22-94. (canceled)
